(19) United States
(12) Patent Application Publication
(10) Pub. No.: US 2025/0088041 A1
(43) Pub. Date: Mar. 13, 2025

(54) WIRELESS POWER TRANSMISSION DEVICE FOR DETECTING HUMAN BODY, AND OPERATING METHOD

(71) Applicant: SAMSUNG ELECTRONICS CO., LTD., Suwon-si (KR)

(72) Inventors: Jaeseok PARK, Suwon-si (KR); Beomwoo Gu, Suwon-si (KR); Sangwook Kwon, Suwon-si (KR); Joonhong Kim, Suwon-si (KR); Jaehyun Park, Suwon-si (KR); Sungku Yeo, Suwon-si (KR)

(73) Assignee: SAMSUNG ELECTRONICS CO., LTD., Suwon-si (KR)

(21) Appl. No.: 18/958,760

(22) Filed: Nov. 25, 2024

Related U.S. Application Data
(63) Continuation of application No. PCT/KR2023/004219, filed on Mar. 29, 2023.

(30) Foreign Application Priority Data
May 24, 2022 (KR) 10-2022-0063681

(51) Int. Cl. H02J 50/60; G01S 13/04; H02J 50/12

(52) U.S. Cl. CPC H02J 50/60; G01S 13/04; H02J 50/12

(57) ABSTRACT

A wireless power transmission device includes: a power transmission coil; a first circuit electrically connected to the power transmission coil and configured to provide first power of a first frequency to the power transmission coil; a sensing antenna configured to detect a human body; a second circuit electrically connected to the sensing antenna; and a controller, where the controller is configured to: control the first circuit to provide the first power of the first frequency to the power transmission coil; control the second circuit to provide a second power of a second frequency, which is different from the first frequency, to the sensing antenna in a state in which the first power is provided to the power transmission coil; and obtain at least one parameter based on at least one sensing result for at least one point of the second circuit from the second circuit.

### CROSS-REFERENCE TO RELATED APPLICATION(S)

This application is a continuation of International Application No. PCT/KR2023/004219, filed on Mar. 29, 2023, in the Korean Intellectual Property Receiving Office, which is based on and claims priority to Korean Patent Application No. 10-2022-0063681, filed on May 24, 2022, in the Korean Intellectual Property Office, the disclosures of which are incorporated by reference herein in their entireties.

### BACKGROUND

### 1. Field

The disclosure relates to a wireless power transmission device for detecting a human body and an operating method.

### 2. Description of Related Art

Portable digital communication devices have become an essential element for many people living today. Consumers want to receive a variety of high-quality services that the consumers want anytime and anywhere. Recently, various sensors, home appliances, and communication devices that exist in our lives have been being networked as one due to the Internet of Things (IoT). To operate various sensors smoothly, a wireless power transmission system may be required. An electronic device that wirelessly receives power may be configured not only as small-scale Bluetooth earphones, wearable devices, and smartphones but also as a large-scale electronic device, such as a robot and a vacuum cleaner. For example, wireless power transmission methods may include a magnetic induction method and a magnetic resonance method. The magnetic induction method is a method defined, for example, by a Wireless Power Consortium (WPC) standard (or Qi standard), in which wireless charging may be performed using a frequency ranging from 100 kHz to 205 kHz. A wireless power transmission device and an electronic device according to the magnetic induction method may be configured to perform wireless charging within a relatively short distance. The magnetic resonance method is a method defined, for example by a AirFuel Alliance (AFA) Standard (or Alliance for Wireless Power (A4WP) standard), in which wireless charging may be performed using a frequency of 6.78 MHz. A wireless power transmission device and an electronic device according to the magnetic resonance method may be configured to perform wireless charging at a relatively long distance compared to the magnetic induction method.

Since wireless charging at a relatively long distance is possible, the effect of electromagnetic waves generated by a wireless power transmission device on a user should be considered. Electromagnetic waves may have harmful effects on humans, and various domestic and foreign organizations are trying to limit electromagnetic waves causing harmful effects on humans. For example, specific absorption rate (SAR) is a value of the rate at which electromagnetic waves radiated from a mobile communication terminal are absorbed by a human body. SAR employs a unit of W/g (or mW/g), which may mean the amount of power (W or mW) absorbed per 1 g of a human body. With concerns about harmful effects of electromagnetic waves on humans arising, SAR limits for mobile communication terminals have been established.

The level of transmission power of a wireless power transmission device should be configured based on SAR limit criteria. However, the Qi standard only discloses a method for detecting the presence of a foreign object based on a Q-factor measurement result using a Q-ping signal and a method for detecting the presence of a foreign object based on wireless charging efficiency measured during power transmission, but does not disclose detection of a human body and determination of the level of transmission power based thereon. In particular, considering a relatively short effective charging distance guaranteed by the Qi standard, practical benefits are insignificant when considering the impact on the human body. The AFA standard only discloses a method for detecting the presence of a foreign object based on a change in impedance measured during a period in which a short beacon signal or a long beacon signal is applied, but does not disclose detection of a human body and determination of the level of transmission power based thereon. In particular, the frequency of 6.78 MHz used in the AFA standard has a relatively low response characteristic in detection of a human body.

### SUMMARY

Provided are a wireless power transmission device and an operating method thereof that may identify the distance to a human body, based on a parameter associated with a radio-frequency (RF) signal of a frequency different from a frequency for wireless power transmission, and may adjust the level of transmission power for charging, based on the identified distance.

Additional aspects will be set forth in part in the description which follows and, in part, will be apparent from the description, or may be learned by practice of the presented embodiments.

According to an aspect of the disclosure, a wireless power transmission device includes: a power transmission coil; a first circuit electrically connected to the power transmission coil and configured to provide first power of a first frequency to the power transmission coil; a sensing antenna configured to detect a human body; a second circuit electrically connected to the sensing antenna; and a controller configured to: control the first circuit to provide the first power of the first frequency to the power transmission coil; control the second circuit to provide a second power of a second frequency, which is different from the first frequency, to the sensing antenna while the first power is provided to the power transmission coil; obtain at least one parameter based on at least one sensing result obtained at at least one point of the second circuit from the second circuit; identify a distance from the sensing antenna to a human body adjacent to the sensing antenna, based on the at least one parameter; and control the first circuit to adjust a level of the first power, based on the distance from the sensing antenna to the human body.

The at least one parameter includes a parameter corresponding to a phase difference between a current and a voltage at the at least one point.

The second circuit may include: a source configured to provide a signal of the second frequency; an amplifier configured to amply the signal of the second frequency to output the signal to the sensing antenna; a coupler connected to the source with the amplifier therebetween and configured to output a forward signal and a reflected signal; an adder configured to output a first waveform of the current, based on an addition result of the forward signal and the reflected signal; and a subtractor configured to output a second waveform of the voltage, based on a subtraction result of the forward signal and the reflected signal.

The second circuit may include: a first zero-crossing detector configured to output a first signal associated with zero-crossing points of the first waveform of the current; a second zero-crossing detector configured to output a second signal associated with zero-crossing points of the second waveform of the voltage; and a phase detector configured to output a phase voltage value corresponding to the phase difference between the current and the voltage based on the first signal and the second signal, and the parameter is the phase voltage value.

The controller may be further configured to identify the distance from the sensing antenna to the human body adjacent to the sensing antenna, based on association information between a plurality of values of the at least one parameter and a plurality of distances to the human body and a value of the at least one parameter.

The controller may be further configured to control the first circuit to adjust the level of the first power, based on the distance from the sensing antenna to the human body, to be less than or equal to a target level satisfying an SAR requirement corresponding to the distance to the human body.

The wireless power transmission device may further include: a sensor configured to sense a current flowing in the power transmission coil, wherein the controller may be further configured to control the first circuit to adjust the level of the first power to be less than or equal to the target level satisfying the SAR requirement corresponding to the distance to the human body, by identifying the current flowing in the power transmission coil sensed by the sensor, and controlling the first circuit to cause the current to be less than or equal to a target current value as the target level.

The first circuit may include: a source configured to supply a signal of the first frequency; an amplifier configured to amplify the signal of the first frequency to provide the signal to the power transmission coil; and a DC/DC converter configured to provide a driving voltage to the amplifier, and wherein the controller may be further configured to control the DC/DC converter to cause the current to be less than or equal to the target current value.

The sensor may include: a pickup coil; and a rectifier configured to rectify AC power by electromagnetic waves generated from the power transmission coil due to application of the first power output from the pickup coil, the controller may be further configured to identify an output voltage of the rectifier, as at least part of an operation of identifying the current flowing in the power transmission coil sensed by the sensor, and control the first circuit to cause the output voltage of the rectifier to be less than or equal to a target voltage value corresponding to the target current value.

The controller may be further configured to control the first circuit to adjust the level of the first power to be less than or equal to the target level satisfying the SAR requirement corresponding to the distance to the human body, by identifying a control value of the first circuit, based on association information between a plurality of distances to the human body and control values of the first circuit and the distance to the human body, and control the first circuit based on the control value.

The first circuit may include: a source configured to provide a signal of the first frequency; an amplifier configured to amplify the signal of the first frequency to provide the signal to the power transmission coil; and a DC/DC converter configured to provide a driving voltage to the amplifier, and the control values of the first circuit are driving voltages provided by the DC/DC converter.

The controller may be further configured to identify the distance from the sensing antenna to the human body adjacent to the sensing antenna by identifying the distance to the human body, based on an object adjacent to the sensing antenna being identified as the human body.

The controller may be further configured to identify that the object adjacent to the sensing antenna is the human body, based on the at least one parameter satisfying a specified first condition or a changed level of the first power applied to the power transmission coil satisfying a specified second condition.

The controller may be further configured to identify that the object adjacent to the sensing antenna is the human body, based on measured results of the at least one parameter at a plurality of times satisfying a specified condition.

The controller may be further configured to identify that the object adjacent to the sensing antenna is the human body, based on measured results of the at least one parameter at a plurality of frequencies satisfying a specified condition.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1A is a block diagram of a wireless power transmission device and a wireless power reception device according to various embodiments;

FIG. 1B and FIG. 1C illustrate a wireless power transmission device according to various embodiments;

FIG. 1D illustrates the structure of a wireless power transmission device according to various embodiments;

FIG. 1E illustrates a hinge structure of a wireless power transmission device according to various embodiments;

FIG. 2A is a block diagram of a wireless power transmission device according to various embodiments;

FIG. 2B illustrates the structure of a power transmission coil and a sensing antenna according to various embodiments;

FIG. 2C illustrates the structure of a power transmission coil and a sensing antenna according to various embodiments;

FIG. 2D illustrates the structure of a power transmission coil and a sensing antenna according to various embodiments;

FIG. 3 illustrates a flowchart illustrating an operating method of a wireless power transmission device according to various embodiments;

FIG. 4A is a block diagram of a wireless power transmission device according to various embodiments;

FIG. 4B illustrates a sensor configured to sense the current of a power transmission coil according to various embodiments;

FIG. 4C illustrates a position where a pickup coil is disposed in a sensor according to various embodiments;

FIG. 5 is a graph illustrating the relationship between the distance to a human body or a conductor and a phase difference;

FIG. 6A is a flowchart illustrating an operating method of a wireless power transmission device according to various embodiments;

FIG. 6B is a flowchart illustrating an operating method of a wireless power transmission device according to various embodiments;

FIG. 6C illustrates the proximity of a human body to a wireless power transmission device at a plurality of times according to various embodiments;

FIG. 6D is a flowchart illustrating an operating method of a wireless power transmission device according to various embodiments;

FIG. 6E illustrates the result of experiments with metal and a human hand according to various embodiments;

FIG. 6F illustrates frequency sweep analysis of metal according to various embodiments;

FIG. 6G illustrates frequency sweep analysis of a human hand according to various embodiments;

FIG. 7A illustrates a coupler according to various embodiments;

FIG. 7B is an equivalent circuit diagram of the coupler of FIG. 7A according to various embodiments;

FIG. 7C may be a sub-equivalent circuit associated with the current of the main line according to various embodiments;

FIG. 7D may be a sub-equivalent circuit associated with the voltage of the main line according to various embodiments;

FIG. 7E illustrates a conversion circuit according to various embodiments;

FIG. 7F illustrates a detection circuit according to various embodiments;

FIG. 8 illustrates SAR according to distance according to various embodiments;

FIG. 9A is a flowchart illustrating an operating method of a wireless power transmission device according to various embodiments;

FIG. 9B is a flowchart illustrating an operating method of a wireless power transmission device according to various embodiments; and

FIG. 10 is a flowchart illustrating an operating method of a wireless power transmission device according to various embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

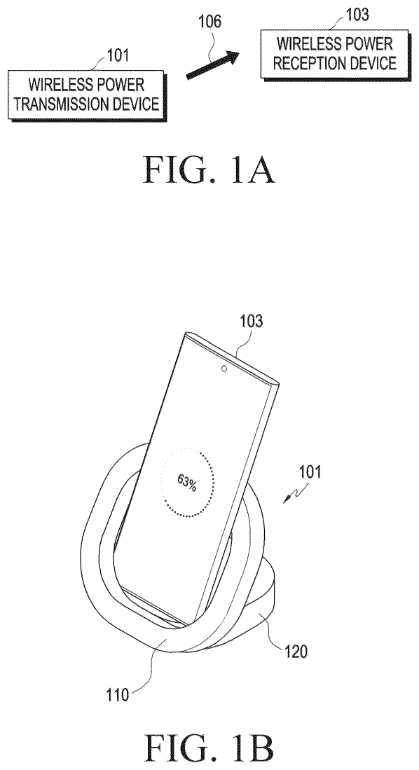

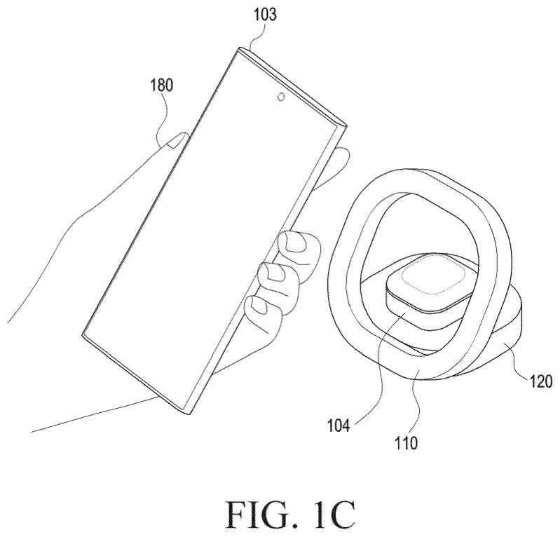

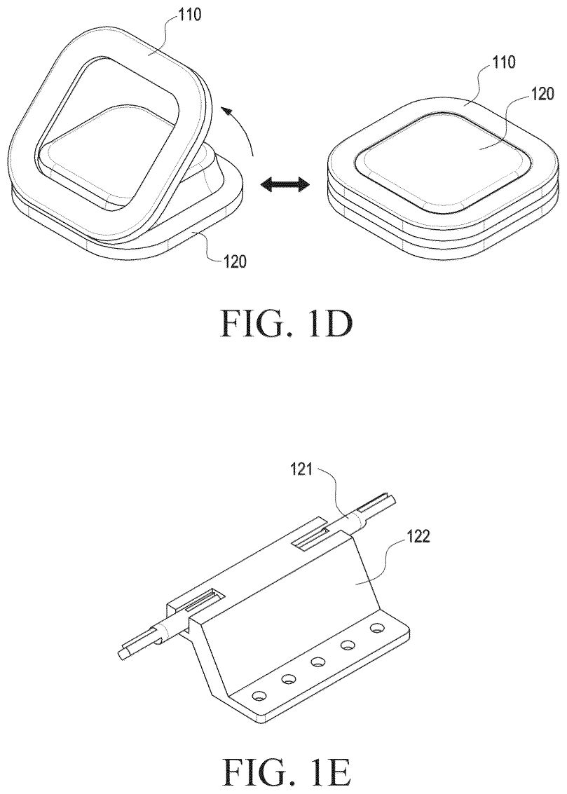

FIG. 1A is a block diagram of a wireless power transmission device and a wireless power reception device according to various embodiments.

Referring to FIG. 1A, the wireless power transmission device 101 according to various embodiments may wirelessly transmit power 106 to the wireless power reception device 103. In one example, the wireless power transmission device 101 may transmit power 106 according to a resonance method. When the wireless power transmission device 101 uses the resonance method, the wireless power transmission device 101 may include, for example, at least one of a power source, a DC-DC conversion circuit (e.g., a DC/DC converter), a DC-AC conversion circuit (e.g., an inverter), an amplifier circuit, an impedance matching circuit, at least one capacitor, at least one coil (e.g., a power transmission coil), or a communication circuit. The at least one capacitor may form a resonant circuit together with the at least one coil. In addition, the wireless power transmission device 101 may include at least one of at least one antenna configured to detect a human body, a circuit configured to process a signal and/or parameter for detecting a human body, or at least one sensor configured to sense the level of a current (or power) applied to the power transmission coil. The wireless power transmission device 101 may include a coil capable of generating an induced magnetic field when a current flows according to an induction method. A process in which the wireless power transmission device 101 generates the induced magnetic field may be expressed as the wireless power transmission device 101 wirelessly transmitting the power 106. Further, in a coil of the wireless power reception device 103, an induced electromotive force (or current, voltage, and/or power) may be generated by a magnetic field generated nearby. A process in which the induced electromotive force is generated through the coil may be expressed as the wireless power reception device 103 wirelessly receiving the power 106. The wireless power transmission device 101 may communicate with the wireless power reception device 103. Those skilled in the art will understand that the wireless power transmission device 101 and the wireless power reception device 103 may transmit and receive data, based on an out-of-band method (e.g., Bluetooth Low Energy (BLE) or various short-range communication methods).

In one example, the wireless power transmission device 101 may transmit the power 106 according to the induction method. When the wireless power transmission device 101 uses the induction method, the wireless power transmission device 101 may include, for example, at least one of a power source, a DC-DC conversion circuit (e.g., a DC/DC converter), a DC-AC conversion circuit (e.g., an inverter), an amplifier circuit, an impedance matching circuit, at least one capacitor, at least one coil, or a communication modulation circuit. The at least one capacitor may form a resonant circuit together with the at least one coil. The wireless power transmission device 101 may be configured by a method defined in the Qi standard of the Wireless Power Consortium (WPC). The wireless power transmission device 101 may include a coil capable of generating an induced magnetic field when a current flows according to the induction method. The wireless power transmission device 101 may communicate with the wireless power reception device 103. For example, the wireless power transmission device 101 may communicate with the wireless power reception device 103 according to an in-band method. The wireless power transmission device 101 may modulate data to be transmitted according to, for example, a frequency-shift keying (FSK) modulation method, and the wireless power reception device 103 may perform modulation according to an amplitude-shift keying (ASK) modulation method, thereby providing information. The wireless power transmission device 101 may identify the information provided by the wireless power reception device 103, based on the amplitude of a current and/or voltage applied to the transmission coil. Those skilled in the art will understand that the wireless power reception device 103 only controls on/off of at least one switch therein. An operation of performing modulation based on the ASK modulation method and/or the FSK modulation method may be understood as an operation of transmitting data (or a packet) according to the in-band communication method, and an operation of performing demodulation based on an ASK demodulation method and/or an FSK demodulation method may be understood as an operation of receiving data (or a packet) according to the in-band communication method.

According to various embodiments, the wireless power transmission device 101 may include both at least one hardware for wireless power transmission based on the resonance method and at least one hardware for wireless power transmission based on the induction method, that is, may support both the resonance method and the induction method. Alternatively, the wireless power transmission device 101 may support only the resonance method. Alternatively, the wireless power transmission device 101 may support only the induction method. In another embodiment, the wireless power transmission device 101 may support an RF method. For example, the wireless power transmission device 101 may include an antenna array including a plurality of antennas, and phase shifters configured to adjust the phase of each of RF signals respectively input to the plurality of antennas of the antenna array. The wireless power transmission device 101 may perform RF-type wireless power transmission by controlling the phase shifters for beamforming to a specific point (or direction). Those skilled in the art will understand that various embodiments implemented in the disclosure document may be applied to at least one of the resonance method, the induction method, or the RF method.

In the disclosure, the wireless power transmission device 101 or the wireless power reception device 103 performing a specific operation may mean that various hardware, for example, a controller (e.g., a micro controlling unit (MCU), a field-programmable gate array (FPGA), an application-specific integrated circuit (ASIC), a microprocessor, or an application processor (AP)), included in the wireless power transmission device 101 or the wireless power reception device 103 performs the specific operation. Alternatively, the wireless power transmission device 101 or the wireless power reception device 103 performing a specific operation may mean that the controller controls other hardware to perform the specific operation. Alternatively, the wireless power transmission device 101 or the wireless power reception device 103 performing a specific operation may mean that the controller or other hardware causes the specific operation to be performed as at least one instruction to perform the specific operation stored in a storage circuit (e.g., memory) of the wireless power transmission device 101 or the wireless power reception device 103 is executed.

FIG. 1B and FIG. 1C illustrate a wireless power transmission device according to various embodiments.

According to various embodiments, the wireless power transmission device 101 may include a first housing 110 and a second housing 120. For example, the first housing 110 may have a ring shape, but the shape thereof is not limited. A hole may be formed in the first housing 110, and the hole may be formed with a size that allows a smartphone, which is a type of wireless power reception device 103, to be placed therein as illustrated in FIG. 1B, but is not limited thereto. At least one power transmission coil, for example, based on the resonance method, may be included (or disposed) in the first housing 110. Power for power transmission may be provided from the power transmission coil included (or disposed) in the first housing 110, and the wireless power reception device 103 placed on the first housing 110 may receive the power. For example, at least one antenna for detecting a human body may be included (or disposed) in the first housing 110. The wireless power transmission device 101 may provide power for detecting a human body and/or identifying the distance to the human body to the at least one antenna. The wireless power transmission device 101 may identify whether a human body is adjacent and/or the distance to the human body by using a parameter based on a result measured while providing the power. The wireless power transmission device 101 may determine the level of power for power transmission, based on whether the human body is adjacent and/or the distance to the human body. For example, as illustrated in FIG. 1C, a user may hold the wireless power reception device 103 with the human body 180 (e.g., a hand). The wireless power transmission device 101 may transmit power for charging the wireless power reception device 103 even when the human body 180 is detected. When the level of electromagnetic waves generated from the wireless power transmission device 101 is relatively high, there is a possibility that an SAR requirement related to the human body 180 may not be satisfied. The wireless power transmission device 101 may adjust the level of power for power transmission, based on whether the human body is adjacent and/or the distance to the human body, and thus the SAR requirement may be satisfied. Identifying whether the human body is adjacent and/or the distance to the human body and adjusting the level of power based on whether the human body is adjacent and/or the distance to the human body will be described later.

At least one power transmission coil based on the induction method may be included (or disposed) in the second housing 120. The wireless power transmission device 101 may identify that another wireless power reception device 104 is positioned on the second housing 120. The wireless power transmission device 101 may wirelessly charge the other wireless power reception device 104, based on the induction method. For example, the wireless power transmission device 101 may at least simultaneously charge the wireless power reception device 103 based on the resonance method and charge the other wireless power reception device 104 based on the induction method.

FIG. 1D illustrates the structure of a wireless power transmission device according to various embodiments. FIG. 1E illustrates a hinge structure of a wireless power transmission device according to various embodiments.

According to various embodiments, as illustrated in FIG. 1D, the first housing 110 may be rotatable with respect to the second housing 120. The wireless power transmission device 101 may include the hinge structure illustrated FIG. 1E, which is connected to the first housing 110. The hinge structure may include, for example, a shaft 121 connected to one housing (e.g., the second housing 120) and a rotatable member 122 capable of rotating about the shaft 121 as an axis. The rotatable member 122 may be connected to another housing (e.g., the first housing 110), and the first housing 110 may be rotatable with respect to the second housing 120 according to the rotation of the rotatable member 122. The hinge structure illustrated in FIG. 1E is merely for illustration, and those skilled in the art will understand that there is no limitation on configuring the hinge structure. For example, the first housing 110 may be rotated so that at least a portion of the second housing 120 is positioned within the hole formed in the first housing 110. In one example, the wireless power transmission device 101 may activate a resonance function when the angle between the first housing 110 and the second housing 120 is equal to or greater than a specified angle, and may deactivate the resonance function when the angle between the first housing 110 and the second housing 120 is less than the specified angle. For example, deactivation of the resonance function may mean non-performance of at least one of a plurality of operations configured for wireless charging based on the resonance method, which is for illustration, and the resonance function may always be activated regardless of the angle between the first housing 110 and the second housing 120. Since the angle between the first housing 110 and the second housing 120 being equal to or greater than the specified angle may indicate that the user intends to place the wireless power reception device 103 on the first housing 110, the wireless power transmission device 101 may determine whether to activate a wireless charging function, based on the angle.

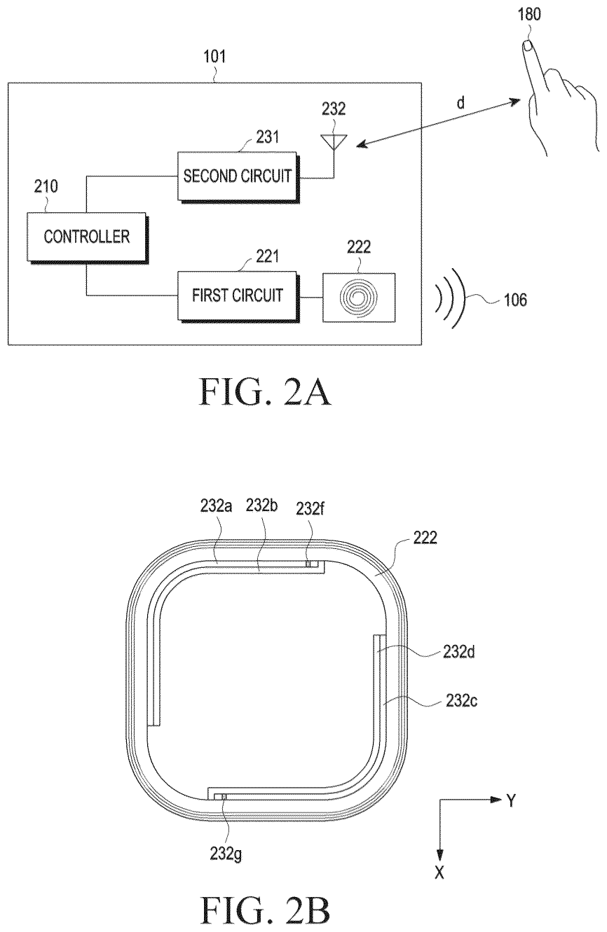

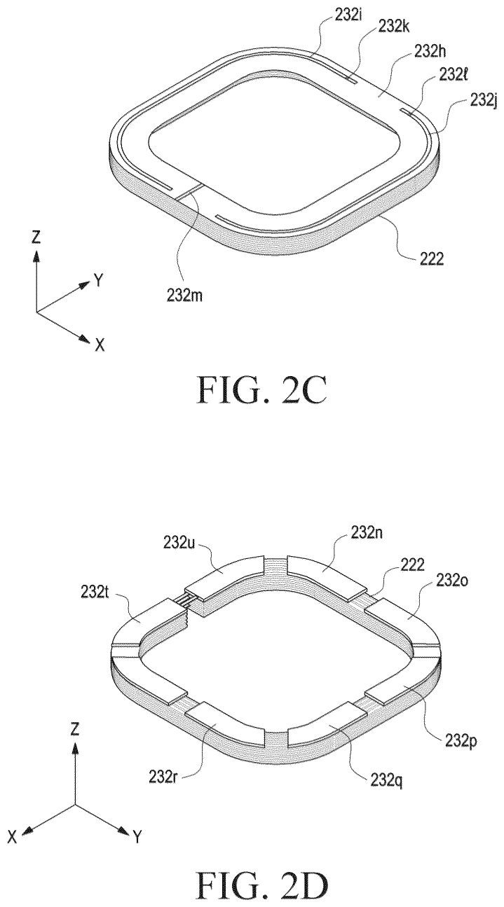

FIG. 2A illustrates a block diagram of a wireless power transmission device according to various embodiments.

According to various embodiments, the wireless power transmission device 101 may include at least one of a controller 210, a first circuit 221, a power transmission coil 222, a second circuit 231, or a sensing antenna 232 configured to detect a human body.

According to various embodiments, the first circuit 221 may be electrically connected to the power transmission coil 222. The first circuit 221 may provide first power of a first frequency (e.g., 6.78 MHz) to the power transmission coil 222. As the first power is provided to the power transmission coil 222, power 106 for wireless charging may be wirelessly transmitted from the power transmission coil 222. The first circuit 221 may include, for example, at least one of at least one hardware configured to generate AC power of the first frequency, at least one hardware configured to amplify the AC power, a matching network, or a sensing circuit, and the detailed configuration of the first circuit 221 will be described later.

According to various embodiments, the second circuit 231 may be electrically connected to the sensing antenna 232. The second circuit 231 may provide second power of a second frequency (e.g., 100 kHz to 1 GHz) to the sensing antenna 232. The second frequency may be configured to a frequency at which a difference in response characteristics is relatively large depending on whether a human body is adjacent and/or a frequency at which a difference in response characteristics is relatively large depending on the distance to the human body. For example, since a difference in response characteristics may be relatively large depending on whether a human body is adjacent and/or the distance to the human body at a frequency included in a band ranging from 100 kHz to 1 GHz, the frequency may be configured as the second frequency but is not limited thereto. Although the first circuit 221 and the second circuit 231 are illustrated and described as different hardware, which is for illustration, those skilled in the art will understand that at least one hardware of the first circuit 221 and at least one hardware of the second circuit 231 may be disposed on a single substrate in another example.

According to various embodiments, the controller 210 may control the first circuit 221 and/or the second circuit 231. The controller 210 may control the first circuit 221 so that the first power of the first frequency is provided to the power transmission coil 222. The controller 210 may, for example, detect a wireless power reception device and perform at least one operation (e.g., establishing a connection for communication, transmitting information about the wireless power transmission device 101, and receiving information about the wireless power reception device) for wireless charging with the wireless power reception device. When the at least one operation is completely performed, the wireless power transmission device 101 may control the first circuit 221 so that the first power for charging the wireless power reception device is provided to the power transmission coil 222. The controller 210 may control the second circuit 231 so that the second power of the second frequency is provided to the sensing antenna 232 while the first power is provided to the power transmission coil 222. The controller 210 may obtain, from the second circuit 231, at least one parameter based on at least one sensing result measured at at least one point of the second circuit 231. In one example, the at least one parameter may be, for example, a phase difference between a voltage and a current at the at least one point (or a phase voltage value corresponding to the phase difference) but is not limited as long as the parameter is for identifying the presence or absence of a human body and/or the distance to the human body, and a method for measuring the phase difference (or the phase voltage value corresponding to the phase difference) will be described later. The second circuit 231 may include at least one hardware configured to output the at least one parameter (e.g., the phase difference between the voltage and the current (or the phase voltage value corresponding to the phase difference)) by using the sensing result (e.g., a voltage and/or current) at the at least one point, which will be described later.

According to various embodiments, the controller 210 may identify whether a human body 180 is adjacent to the sensing antenna 232 and/or the distance d from the sensing antenna 232 to the human body 180, based on the at least one parameter provided from the second circuit 231. The distance d from the sensing antenna 232 to the human body 180 may also be referred to (or managed) as the distance from the wireless power transmission device 101 to the human body 180. For example, the controller 210 may identify the distance to the human body 180 by referring to association information between the at least one parameter and the distance to the human body 180. For example, the controller 210 may identify whether the human body 180 is present by referring to association information between the at least one parameter and whether the human body 180 is present. The controller 210 may control the first circuit 221 to adjust the level of the first power, based on the distance d from the sensing antenna 232 to the human body 180. For example, the controller 210 may determine the level of the first power, based on the distance d to the human body 180, so that the SAR requirement may be satisfied. For example, the controller 210 may determine the level of the first power by referring to association information between the distance d to the human body 180 and the level of power that enables the SAR requirement to be satisfied. The level of the first power may be, for example, an output voltage (also referred to, for example, as a DC level) of a DC/DC converter included in the first circuit 180, but is not limited in type. Alternatively, the controller 210 may identify the distance d to the human body 180 and a target level of a current applied to the power transmission coil 222 that enables the SAR requirement to be satisfied. The controller 210 may monitor the level of the current applied to the power transmission coil 222, and may control the output voltage (also referred to, for example, as the DC level) of the DC/DC converter included in the first circuit 180 so that the level of the current is less than or equal to the target level. The controller 210 may be configured as an MCU, an FPGA, an ASIC, a microprocessor, or an AP, but those skilled in the art will understand that the controller is not limited as long as being any hardware for performing the foregoing operations. As described above, even when the human body 180 is adjacent, the wireless power transmission device 101 may maintain wireless charging for the wireless power reception device while satisfying the SAR requirement. Those skilled in the art will understand that embodiments of the disclosure for satisfying various SAR requirements may also be implemented to satisfy a power density (PD) requirement or a requirement for simultaneous occurrence of SAR and PD. In addition, those skilled in the art will understand that embodiments of the disclosure for satisfying the SAR requirement at various specific times (or specific moments) may also be implemented to satisfy a cumulative SAR (or average SAR) requirement for a certain period.

FIG. 2B illustrates the structure of a power transmission coil and a sensing antenna according to various embodiments.

According to various embodiments, the sensing antenna 232 may be configured as an inverted antenna (IFA). At least one sub-antenna 232a and 232b forming the sensing antenna 232 may be disposed on a substrate 232b and 232c and be disposed, for example, inside the power transmission coil 222, but those skilled in the art will understand that there is no limitation on a position where the sub-antenna is disposed. A port 232f and 232g for feeding may be disposed (or defined) in each the sub-antennas 232a and 232b.

FIG. 2C illustrates the structure of a power transmission coil and a sensing antenna according to various embodiments.

According to various embodiments, the sensing antenna 232 may be configured as a slot antenna. The sensing antenna 232 may be disposed, for example, on the power transmission coil 222. The sensing antenna 232 may be in direct contact with the power transmission coil 222, or an intermediary structure (e.g., a substrate) may be disposed between the sensing antenna 232 and the power transmission coil 222. The sensing antenna 232 may include a conductor 232h, and at least one slot 232i, 232j, and 232m may be disposed in the conductor 232h. A port 232k and 232l for feeding may be formed (or defined) across at least some slots 232i and 232j.

FIG. 2D illustrates the structure of a power transmission coil and a sensing antenna according to various embodiments.

According to various embodiments, the sensing antenna 232 may be configured as a zero-order (ZOR) antenna. The sensing antenna 232 may be disposed, for example, on the power transmission coil 222. The sensing antenna 232 may be in direct contact with the power transmission coil 222, or an intermediary structure (e.g., a substrate) may be disposed between the sensing antenna 232 and the power transmission coil 222. The sensing antenna 232 may include at least one sub-antenna 232n, 232o, 232p, 232q, 232r, 232s, 232t, and 232u, but is not limited thereto.

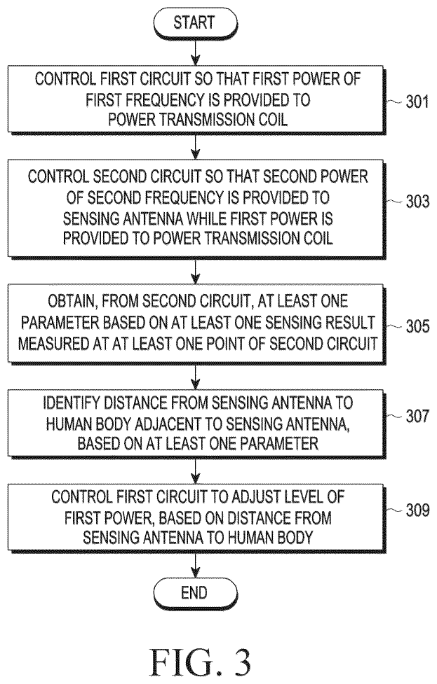

FIG. 3 illustrates a flowchart illustrating an operating method of a wireless power transmission device according to various embodiments.

According to various embodiments, in operation 301, the wireless power transmission device 101 (e.g., a controller 210) may control a first circuit 221 so that first power of a first frequency is provided to a power transmission coil 222. For example, the wireless power transmission device 101 may control the first circuit 221 to provide the first power of the first frequency (e.g., 6.78 MHz) to the power transmission coil 222. For example, when detecting a wireless power reception device and/or completely performing at least one operation for wireless charging with the wireless power reception device, the wireless power transmission device 101 may control the first circuit 221 so that the first power for charging the wireless power reception device is provided to the power transmission coil 222. In operation 303, the wireless power transmission device 101 may control a second circuit 231 so that second power of a second frequency is provided to a sensing antenna 223 while the first power is provided to the power transmission coil 222.

According to various embodiments, the wireless power transmission device 101 may obtain, from the second circuit 231, at least one parameter based on at least one sensing result measured at at least one point of the second circuit 231 while the second power is provided. For example, the wireless power transmission device 101 may obtain, as the at least one parameter, a phase difference between a voltage and a current at the at least one point (or a phase voltage value corresponding to the phase difference), but there is no limitation on the type of the at least one parameter. In operation 307, the wireless power transmission device 101 may identify whether a human body 180 is adjacent to a sensing antenna 232 and/or the distance d from the sensing antenna 232 to the human body 180, based on the at least one parameter provided from the second circuit 231. For example, the wireless power transmission device 101 may identify the distance to the human body 180 by referring to association information between the at least one parameter and the distance to the human body 180. In operation 309, the wireless power transmission device 101 may control the first circuit 221 to adjust the level of the first power, based on the distance d from the sensing antenna 232 to the human body 180. For example, the wireless power transmission device 101 may determine the level of the first power, based on the distance d to the human body 180, so that the SAR requirement may be satisfied. For example, the controller 210 may determine the level of the first power by referring to association information between the distance d to the human body 180 and the level of power that enables the SAR requirement to be satisfied. Alternatively, the wireless power transmission device 101 may identify the distance d to the human body 180 and a target level of a current applied to the power transmission coil 222 that enables the SAR requirement to be satisfied. The wireless power transmission device 101 may monitor the level of the current applied to the power transmission coil 222, and may control an output voltage (also referred to, for example, as a DC level) of a DC/DC converter included in the first circuit 221 so that the level of the current is less than or equal to the target level.

Although the wireless power transmission device 101 has been described above as identifying whether the human body is present and/or the distance to the human body, based on the phase difference between the voltage and the current, which is for illustration, those skilled in the art will understand that the wireless power transmission device 101 may also identify whether the human body is present and/or the distance to the human body, based on voltage and current gains, or identify whether the human body is present and/or the distance to the human body by using both the phase difference and the gains, that is, by using impedance.

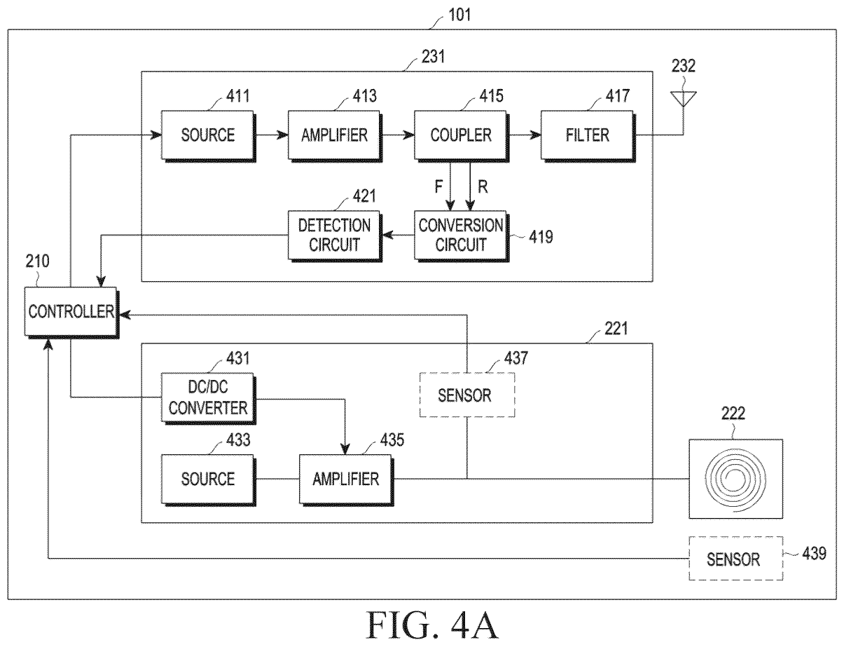

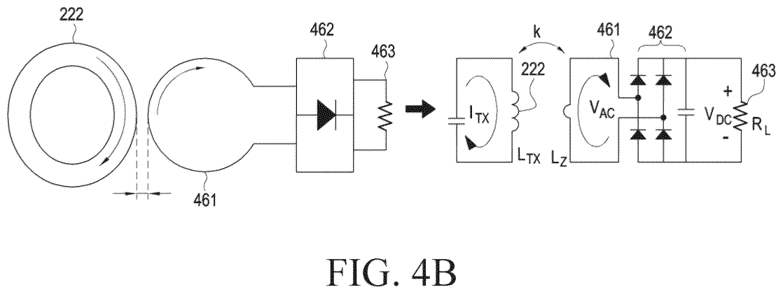

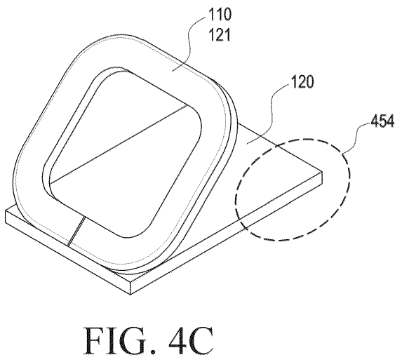

FIG. 4A illustrates a block diagram of a wireless power transmission device according to various embodiments.

According to various embodiments, the wireless power transmission device 101 may include at least one of a controller 210, a first circuit 221, a power transmission coil 222, a second circuit 231, a sensing antenna 232 configured to detect a human body, or a sensor 439.

According to various embodiments, the first circuit 221 may include at least one of a DC/DC converter 431, a source 433, an amplifier 435, or a sensor 437. The DC/DC converter 431 may provide a driving voltage to the amplifier 435. The amplifier 435 may be configured, for example, as a class-D amplifier or a class-E amplifier, but the class of the amplifier 435 is not limited. The amplifier 435 may output AC power, for example, based on a gate voltage from the source 433. The source 433 is not limited as long as being any device capable of outputting a gate voltage of a first frequency. The source 433 may include an element configured to output a signal of the first frequency (e.g., 6.78 MHz) and an element configured to generate a gate voltage by using the signal. Alternatively, the source 433 may refer only to the element configured to output the signal of the first frequency, in which case it will be understood by those skilled in the art that a gate driver is additionally connected to the source 433 and the amplifier 435 therebetween. The controller 210 may control the level of transmission power, for example, by controlling the level of an output voltage (i.e., a DC level) of the DC/DC converter 431. The sensor 437 may sense a current and/or voltage at an input terminal of the power transmission coil 222, and may provide a sensing result to the controller 210. The controller 210 may identify impedance, based on the sensed current and/or voltage, and perform foreign object detection (FOD) based on the impedance, which is for illustration, and the sensor 437 may not be included in the wireless power transmission device 101 depending on a configuration. In this case, the wireless power transmission device 101 may perform FOD, based on at least one parameter from the second circuit 231. Alternatively, the sensing result from the sensor 437 may be used to perform FOD based on an AFA standard, and the at least one parameter from the second circuit 231 may be used to adjust the level of power for charging, but the disclosure is not limited.

According to various embodiments, the second circuit 231 may include at least one of a source 411, an amplifier 413, a coupler 415, a filter 417, a conversion circuit 419, or a detection circuit 421. The source 411 may output a signal of a second frequency. For example, the source 411 may change the frequency of the output signal according to control of the controller 210. The controller 210 may control a frequency change by the source 411 through an SPI, but the type of an interface is not limited. The source 411 may include, but is not limited to, a voltage-controlled oscillator (VCO) and/or a phase-locked loop (PLL). The amplifier 413 may amplify and output the signal output from the source 411. The coupler 415 may be configured, for example, as a directional coupler. Accordingly, the coupler 415 may output a forward signal F and a reflected signal R. The filter 417 may include, for example, at least one band-pass filter and/or at least one band-stop filter. For example, the at least one band-pass filter may pass a band including the second frequency. For example, the at least one band-stop filter may block a band including the first frequency. For example, an induced electromotive force of the first frequency may be generated in the sensing antenna 232 due to electromagnetic waves generated from the power transmission coil 222. The induced electromotive force of the first frequency is a noise component, and may thus be filtered by the at least one band-stop filter.

According to various embodiments, the conversion circuit 419 may receive the forward signal F and the reflected signal R from the coupler 415. The conversion circuit 419 may provide a current waveform and a voltage waveform, based on the forward signal F and the reflected signal R. For example, the conversion circuit 419 may include at least one OP-AMP. An OP-AMP having a summing function may output the current waveform by adding the forward signal F and the reflected signal R. An OP-AMP having a subtraction function may output the voltage waveform by subtracting the forward signal F and the reflected signal R. The detection circuit 421 may receive the current waveform and the voltage waveform from the conversion circuit 419. The detection circuit 421 may output a parameter corresponding to the phase difference between a current and a voltage by using the current waveform and the voltage waveform. In one example, the parameter may be a phase voltage value corresponding to the phase difference, but is not limited thereto, and the phase voltage value will be described later. The controller 210 may receive the parameter corresponding to the phase difference from the detection circuit 421. The controller 210 may determine whether a human body 180 is adjacent to the sensing antenna 232 and/or the distance d from the sensing antenna 232 to the human body 180, based on the parameter corresponding to the phase difference. For example, the controller 210 may determine the distance to the human body 180 by referring to association information between at least one parameter and the distance to the human body 180. The controller 210 may control the DC/DC converter 431 of the first circuit 221 to adjust the level of first power, based on the distance d from the sensing antenna 232 to the human body 180. For example, the controller 210 may determine the level of the first power, based on the distance d to the human body 180, so that an SAR requirement may be satisfied. For example, the controller 210 may control the DC/DC converter 431 by referring to association information between the distance d to the human body 180 and the level of power that enables the SAR requirement to be satisfied. Alternatively, the controller 210 may identify the distance d to the human body 180 and a target level of a current applied to the power transmission coil 222 that enables the SAR requirement to be satisfied. The wireless power transmission device 101 may monitor the level of the current applied to the power transmission coil 222, and may control the DC/DC converter 431 so that the level of the current is less than or equal to the target level. For example, the controller 210 may receive the level of the current applied to the power transmission coil 222 from the sensor 439. The controller 210 may monitor the level of the current applied to the power transmission coil 222 from the sensor 439, and may control the DC/DC converter 431 so that the level of the current is less than or equal to the target level. Accordingly, the SAR requirement for the human body 180 may not be violated.

FIG. 4B illustrates a sensor configured to sense the current of a power transmission coil according to various embodiments. FIG. 4C illustrates a position where a pickup coil is disposed in a sensor.

According to various embodiments, the sensor 439 of FIG. 4A may include at least one of a pickup coil 461, a rectifier 462, or a load 463. The pickup coil 461 may be disposed adjacent to the power transmission coil 222, and the distance thereof may be configured relatively short but is not limited thereto. For example, as illustrated in FIG. 4C, the pickup coil 461 may be disposed in a first position 454 of a second housing 120, and may be disposed relatively close to the power transmission coil 222. The orientation of the pickup coil 461 may be determined so that the power transmission coil 222 and the pickup coil 461 are not vertical even though the first housing 110 is rotated, which is for illustration and is not limited. A right circuit diagram of FIG. 4B may be an equivalent circuit for the power transmission coil 222 and the sensor 439. Referring to the equivalent circuit, a current of I_{TX} may be applied to the power transmission coil 222. The current may be a current for charging Itx. The power transmission coil 222 and the pickup coil 461 may be coupled to each other as being disposed with a relatively close distance, and a coupling coefficient may be k. An induced electromotive force may be generated in the pickup coil 461 by coupling of the coils 222 and 461, and an AC voltage V_{AC} may be applied. The AC voltage V_{AC} may be as shown in Equation 1.

$$[ Equation 1 ]$$

$${V}_{AC} = j ω k \sqrt{{L}_{TX} {L}_{2}} \cdot {I}_{TX}$$

In Equation 1, ω is the angular frequency of the alternating current I_{TX}, L_{TX} is the inductance of the power transmission coil 222, and L₂ is the inductance of the pickup coil 461. The relationship between a DC voltage V_{DC} rectified by the rectifier 462 and I_{TX} may be as shown in Equation 2.

$$[ Equation 2 ]$$

$${I}_{TX} = \frac{{V}_{DC}}{\sqrt{2} \sqrt{{L}_{TX} {L}_{2}}}$$

The controller 210 may identify the current I_{TX} flowing in the power transmission coil 222, based on the voltage V_{DC} measured by the sensor 439. The controller 210 may control the DC/DC converter 431 so that the current I_{TX} flowing in the power transmission coil 222 satisfies an SAR requirement. For example, the controller 210 may identify the distance d to the human body 180, and may identify a target current (or the maximum value of the current) for satisfying an SAR requirement corresponding to the distance d. Information about relationships between target currents (or the maximum values of the current) for satisfying SAR requirements and a plurality of distances may be stored in advance in the wireless power transmission device 101. For example, the controller 210 may identify the target current (or the maximum value of the current) corresponding to the identified distance d, based on the information about the relationships. The controller 210 may continuously monitor the measured voltage V_{DC} to control the DC/DC converter 431 so that a current less than or equal to the target current (or the maximum value of the current) flows in the power transmission coil 222.

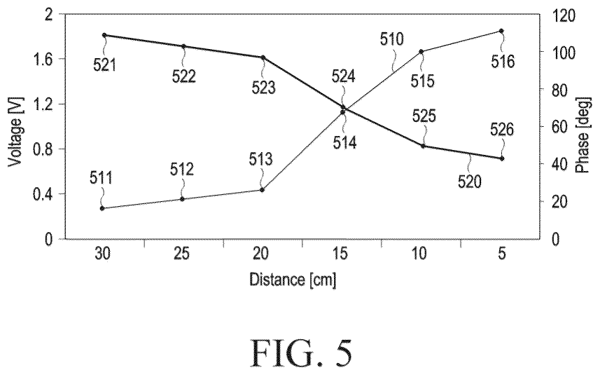

As described above, in one example, the controller 210 may identify the distance to the human body 180, based on a parameter (e.g., a phase voltage value) corresponding to a phase difference between a current and a voltage at at least one point of the second circuit 231. FIG. 5 is a graph illustrating the relationship between the distance to a human body or a conductor and a phase difference. A first graph 510 may be a graph corresponding to the human body, and a second graph 520 may be a graph corresponding to the conductor. For example, when the distance to the human body 180 is 30 cm, the phase difference may be 14.4 degrees (511), when the distance to the human body 180 is 25 cm, the phase difference may be 19.2 degrees (512), when the distance to the human body 180 is 15 cm, the phase difference may be 24 degrees (513), when the distance to the human body 180 is 10 cm, the phase difference may be 100.8 degrees (514), and when the distance to the human body 180 is 5 cm, the phase difference may be 110.4 degrees (515). For example, when the distance to the conductor is 30 cm, the phase difference may be 105.6 degrees (521), when the distance to the conductor is 25 cm, the phase difference may be 100.8 degrees (522), when the distance to the conductor is 20 cm, the phase difference may be 96 degrees (523), when the distance to the conductor is 15 cm, the phase difference may be 72 degrees (524), when the distance to the conductor is 10 cm, the phase difference may be 48 degrees (524), and when the distance to the conductor is 5 cm, the phase difference may be 43.4 degrees (525). A wireless power transmission device 101 may store information about the phase difference according to the distance to the human body (or information about the parameter corresponding to the phase difference), such as the first graph 510 of FIG. 5. The wireless power transmission device 101 may store information about the phase difference according to the distance to the conductor (or information about a parameter corresponding to the phase difference), such as the second graph 520 of FIG. 5. In one example, the parameters corresponding to the phase differences may be a phase voltage value corresponding to the phase difference, which will be described in detail later. A left y-axis of FIG. 5 may be identified as being expressed in V, which is a unit for a phase voltage value. In one example, the phase difference may be proportional to the phase voltage value, which will be described later. For example, the wireless power transmission device 101 may identify the distance to the human body 180, based on a measured phase difference (or a parameter corresponding to the phase difference) and relationship information (e.g., relationship information, such as the first graph 510 of FIG. 5). The wireless power transmission device 101 may identify a target current value (or a maximum current value) for satisfying an SAR requirement corresponding to the distance to the human body 180. For example, when the phase difference is identified as 24 degrees, the wireless power transmission device 101 may identify that the distance to the human body 180 is 15 cm, based on the relationship information, such as the first graph 510. The wireless power transmission device 101 may identify a target current (or a maximum current value) for satisfying an SAR requirement corresponding to the distance of 15 cm.

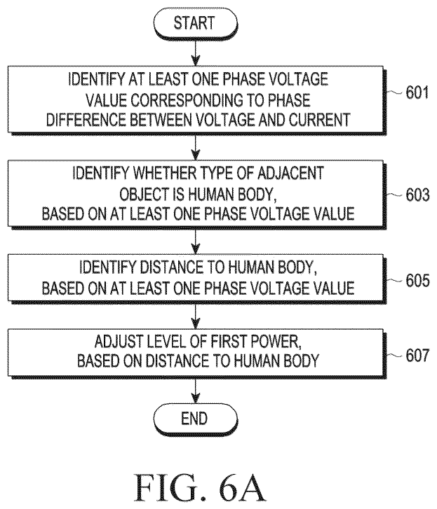

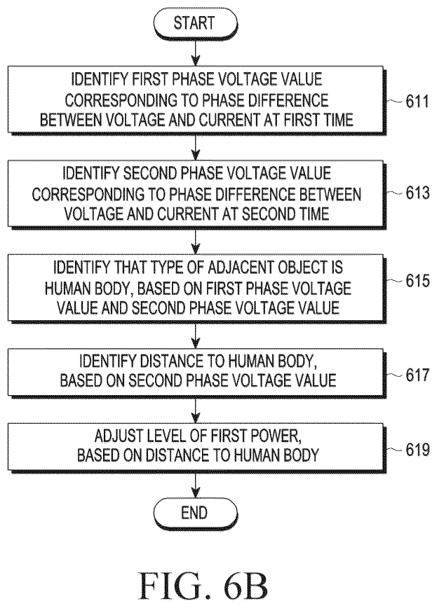

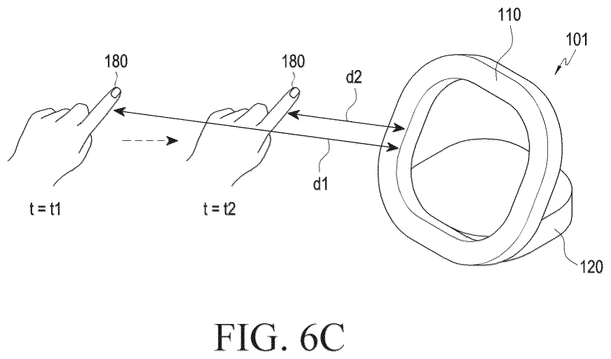

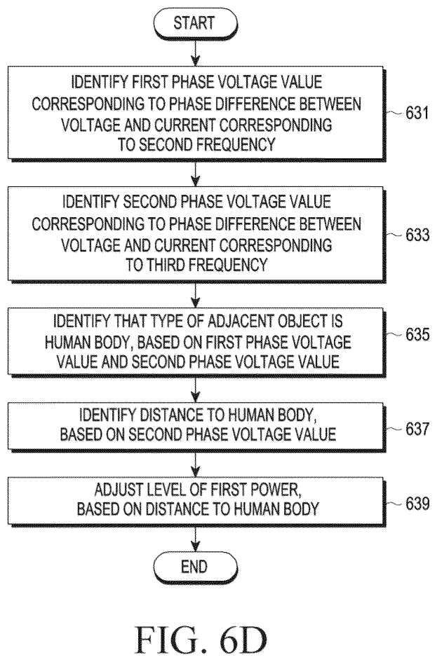

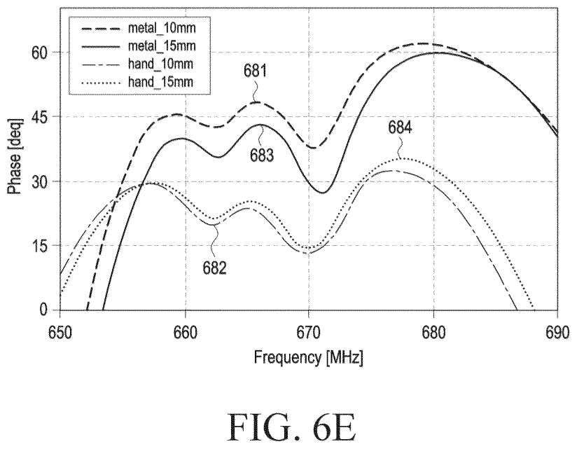

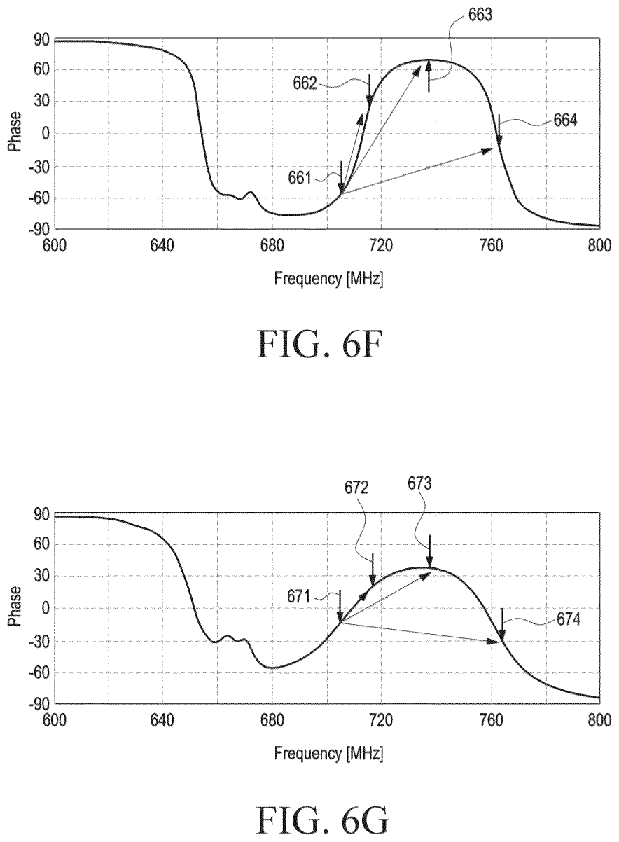

FIG. 6A is a flowchart illustrating an operating method of a wireless power transmission device according to various embodiments.

According to various embodiments, in operation 601, the wireless power transmission device 101 (e.g., a controller 210) may identify at least one phase voltage value corresponding to a phase difference between a voltage and a current at at least one point of a second circuit 231. As described in FIG. 5, the phase difference between the voltage and the current at the at least one point of the second circuit 231 may change according to the distance to a human body 180. The phase voltage value is an example of a parameter corresponding to, for example, the phase difference detected by a detection circuit 421, and it will be understood by those skilled in the art that the value may be replaced with any other value corresponding to the phase difference without limitation. In operation 603, the wireless power transmission device 101 may identify whether the type of an adjacent object is a human body, based on the at least one phase voltage value. As described in FIG. 5, the phase difference between the voltage and the current at the at least one point of the second circuit 231 when the human body is adjacent may be different from the phase difference between the voltage and the current at the at least one point of the second circuit 231 when a conductor is adjacent. The wireless power transmission device 101 may identify whether the adjacent object is the human body, based on the detected phase difference. In one example, the wireless power transmission device 101 may identify whether the adjacent object is the human body, based on the result of measuring the phase difference at two or more times, which will be described in detail later. In one example, the wireless power transmission device 101 may identify whether the adjacent object is the human body, based on a measurement result at a plurality of frequencies, which will be described in detail later.

According to various embodiments, in operation 605, the wireless power transmission device 101 may identify the distance to the human body, based on the at least one phase voltage value. The wireless power transmission device 101 may store association information between one or more phase voltage values and distances to the human body. The wireless power transmission device 101 may store relationship information between the parameter (e.g., the phase voltage value) corresponding to the phase difference and the distance to the human body instead of (or in addition to) the relationship information between the phase difference and the distance to the human body of FIG. 5. The wireless power transmission device 101 may identify the distance to the human body corresponding to the phase voltage value, based on the relationship information between the parameter (e.g., the phase voltage value) corresponding to the phase difference and the distance to the human body. In operation 607, the wireless power transmission device 101 may adjust the level of first power for charging a wireless power reception device 103, based on the distance to the human body. The wireless power transmission device 101 may identify a target level (or maximum level) of the first power for satisfying an SAR requirement based on the distance to the human body identified in operation 605. The wireless power transmission device 101 may adjust the level of the first power to be less than or equal to the target level (or maximum level) for satisfying the SAR requirement. In one example, the wireless power transmission device 101 may adjust the level of the first power by controlling a first circuit 221 (e.g., the DC/DC converter 431), but a method for adjusting the level is not limited.

In one example, the wireless power transmission device 101 may identify whether an approaching object is a human body or a conductor, based on whether an identified phase difference is greater than or equal to a threshold value, which is described with reference to FIG. 6E.

In one example, the wireless power transmission device 101 may also determine whether an approaching object is a human body, based on a change in the level of a current applied to a power transmission coil 222. For example, when a conductor is adjacent to the power transmission coil 222, the level of the current applied to the power transmission coil 222 may decrease by a relatively large level. For example, when a human body is adjacent to the power transmission coil 222, the level of the current applied to the power transmission coil 222 may hardly change. Accordingly, the wireless power transmission device 101 may identify the approach of the object, based on a parameter (e.g., a phase voltage value) corresponding to a phase difference, and may identify whether the approaching object is the human body or the conductor, based on whether the change in the level of the current applied to the power transmission coil 222 is greater than or equal to a threshold level. For example, the wireless power transmission device 101 may identify the approaching object is the conductor when the change in the level of the current applied to the power transmission coil 222 is greater than or equal to the threshold level. For example, the transmission device 101 may identify that the approaching object is the human body when the change in the level of the current applied to the power transmission coil 222 is less than the threshold level. When identifying that the approaching object is the human body, the wireless power transmission device 101 may identify the distance to the human body, based on the parameter (e.g., the phase voltage value) corresponding to the phase difference.

Those skilled in the art will understand that the wireless power transmission device 101 according to various embodiments of the disclosure may determine whether an approaching object is a human body, based on a parameter (e.g., a phase voltage value) corresponding to a phase difference and/or a change in the level of a current applied to the power transmission coil 222.

FIG. 6B is a flowchart illustrating an operating method of a wireless power transmission device according to various embodiments. The embodiments of FIG. 6B will be described with reference to FIG. 6C. FIG. 6C illustrates the proximity of a human body to a wireless power transmission device at a plurality of times according to various embodiments.

Referring to FIG. 6B, according to various embodiments, in operation 611, the wireless power transmission device 101 (e.g., a controller 210) may identify a first phase voltage value corresponding to a phase difference between a voltage and a current at a first time. For example, as illustrated in FIG. 6C, a human body 180 may be away from the wireless power transmission device 101 by a first distance dl at the first time t1. The wireless power transmission device 101 may identify the first phase voltage value corresponding to the phase difference between the voltage and the current at at least one point of a second circuit 231. A user may bring the human body 180 adjacent to the wireless power transmission device 101. At a second time point t2, the human body 180 may be away from the wireless power transmission device 101 by the first distance dl. Referring back to FIG. 6A, in operation 613, the wireless power transmission device 101 may identify a second phase voltage value corresponding to a phase difference between a voltage and a current at a second time. The wireless power transmission device 101 may identify the second phase voltage value corresponding to the phase difference between the voltage and the current at at least one point of the second circuit 231.

According to various embodiments, in operation 615, the wireless power transmission device 101 may identify that the type of an adjacent object is a human body, based on the first phase voltage value and the second phase voltage value. For example, the wireless power transmission device 101 may identify that the type of the adjacent object is the human body when the varying direction of the first phase voltage value and the second phase voltage value is a varying direction corresponding to the approach of the human body. For example, the wireless power transmission device 101 may identify that the type of the adjacent object is a conductor when the varying direction of the first phase voltage value and the second phase voltage value is a varying direction corresponding to the approach of the conductor. For example, as illustrated in the first graph 510 of FIG. 5, when the human body approaches (i.e., when the distance decreases), the phase difference may increase. For example, as illustrated in the second graph 520 of FIG. 5, when the conductor approaches (i.e., when the distance decreases), the phase difference may decrease. The varying direction of the phase difference when the human body approaches may be different from the varying direction of the phase difference when the conductor approaches. Accordingly, the varying direction of a parameter (e.g., a phase voltage value) corresponding to the phase difference when the human body approaches may be different from the varying direction of a parameter (e.g., a phase voltage value) corresponding to the phase difference when the conductor approaches. Accordingly, the wireless power transmission device 101 may identify whether the type of the adjacent object is the human body or the conductor, based on the varying directions of the parameters (e.g., the phase voltage values) corresponding to the phase differences. In the embodiments of FIG. 6B, it is assumed that the type of the adjacent object is the human body, based on the varying directions of the parameters (e.g., the phase voltage values) corresponding to the phase differences at the first time t1 and the second time t2 being the varying direction corresponding to the human body.

According to various embodiments, in operation 617, the wireless power transmission device 101 may identify the distance to the human body, based on the second phase voltage value. For example, the wireless power transmission device 101 may identify the distance to the human body corresponding to the second phase voltage value, based on relationship information between phase voltage values and distances to the human body. In operation 619, the wireless power transmission device 101 may adjust the level of first power for charging a wireless power reception device 103, based on the distance to the human body. The wireless power transmission device 101 may identify a target level (or maximum level) of the first power for satisfying an SAR requirement based on the distance to the human body identified in operation 617. The wireless power transmission device 101 may adjust the level of the first power to be less than or equal to the target level (or maximum level) for satisfying the SAR requirement.

FIG. 6D is a flowchart illustrating an operating method of a wireless power transmission device according to various embodiments.

According to various embodiments, in operation 631, the wireless power transmission device 101 (e.g., a controller 210) may identify a first phase voltage value corresponding to a phase difference between a voltage and a current corresponding to a second frequency for detecting a human body. For example, the wireless power transmission device 101 may control a source 411 to output a signal of the second frequency for detecting a human body. The wireless power transmission device 101 may identify the first phase voltage value corresponding to the phase difference between the voltage and the current at at least one point of a second circuit 231 while the signal of the second frequency for detecting the human body is applied to a sensing antenna 232. In operation 633, the wireless power transmission device 101 (e.g., the controller 210) may identify a second phase voltage value corresponding to a phase difference between a voltage and a current corresponding to a third frequency for detecting a human body. For example, the wireless power transmission device 101 may control the source 411 to output a signal of the third frequency for detecting a human body. That is, the wireless power transmission device 101 may change the frequency of the signal from the source 411 from the second frequency to the third frequency. The wireless power transmission device 101 may identify the second phase voltage value corresponding to the phase difference between the voltage and the current at at least one point of the second circuit 231 while the signal of the third frequency for detecting the human body is applied to the sensing antenna 232.

According to various embodiments, in operation 635, the wireless power transmission device 101 may identify that the type of an adjacent object is a human body, based on the first phase voltage value and the second phase voltage value. For example, the wireless power transmission device 101 may identify that the type of the adjacent object is the human body when the varying direction of the first phase voltage value and the second phase voltage value is a varying direction due to a change in frequency corresponding to the human body. For example, the wireless power transmission device 101 may identify that the type of the adjacent object is a conductor when the varying direction of the first phase voltage value and the second phase voltage value is a varying direction due to a change in frequency corresponding to the conductor. For example, the varying direction of a phase difference according to a frequency change when the human body is adjacent may be different from the varying direction of a phase difference according to a frequency change when the conductor is adjacent. Accordingly, the varying direction of a parameter (e.g., a phase voltage value) corresponding to the phase difference when the human body is adjacent may be different from the varying direction of a parameter (e.g., a phase voltage value) corresponding to the phase difference when the conductor is adjacent. Accordingly, the wireless power transmission device 101 may identify whether the type of the adjacent object is the human body or the conductor, based on the varying directions of the parameters (e.g., the phase voltage values) corresponding to the phase differences according to the frequency changes. In the embodiments of FIG. 6D, it is assumed that the type of the adjacent object is the human body, based on the varying directions of parameters (e.g., the phase voltage values) corresponding to the phase differences respectively corresponding to the second frequency and the third frequency being a varying direction corresponding to the human body.

According to various embodiments, in operation 637, the wireless power transmission device 101 may identify the distance to the human body, based on the second phase voltage value. For example, the wireless power transmission device 101 may identify the distance to the human body corresponding to the second phase voltage value, based on relationship information between phase voltage values and distances to the human body. In operation 639, the wireless power transmission device 101 may adjust the level of first power for charging a wireless power reception device 103, based on the distance to the human body. The wireless power transmission device 101 may identify a target level (or maximum level) of the first power for satisfying an SAR requirement based on the distance to the human body identified in operation 637. The wireless power transmission device 101 may adjust the level of the first power to be less than or equal to the target level (or maximum level) for satisfying the SAR requirement. When identifying that the type of the adjacent object is the conductor, the wireless power transmission device 101 may identify the distance to the conductor. The wireless power transmission device 101 may adjust the level of the first power, based on the distance to the conductor. For example, when the distance to the conductor is relatively long, the wireless power transmission device 101 may control a relatively large level of the first power to be provided, but is not limited thereto.

FIG. 6E illustrates the result of experiments with metal and a human hand according to various embodiments.

FIG. 6E shows phase differences 681 at various frequencies when the metal is 10 mm away from a sensing antenna 232 and phase differences 682 at various frequencies when the human hand is 10 mm away from the sensing antenna 232. In addition, phase differences 683 at various frequencies when the metal is 15 mm away from the sensing antenna 232 and phase differences 684 at various frequencies when the human hand is 15 mm away from the sensing antenna 232 are shown. For example, it may be identified that the phase differences corresponding to the metal increases but the phase differences corresponding to the human hand decreases as the frequency changes from 675 MHz to 680 MHz. Accordingly, whether an adjacent object is a human body or a conductor may be identified based on phase difference values according to a frequency sweep. Alternatively, a wireless power transmission device 101 may identify whether the adjacent object is the human body, based on the absolute value of a phase difference at a specific frequency. For example, at a frequency of 680 MHz, a phase difference corresponding to the human body and a phase difference corresponding to the conductor may be different, and whether the adjacent object is the human body may be determined by configuring a threshold value for distinguishing the phase differences.

FIG. 6F illustrates frequency sweep analysis of metal according to various embodiments. FIG. 6G illustrates frequency sweep analysis of a human hand according to various embodiments.

FIG. 6F shows a phase difference in a frequency sweep from 600 MHz to 800 MHz with respect to metal. A wireless power transmission device 101 may configure first data 661 at a first frequency as a reference. The wireless power transmission device 101 may identify pieces of data 662, 663, and 664 at other frequencies, and may identify slopes thereof compared to the reference. FIG. 6G shows a phase difference in a frequency sweep from 600 MHz to 800 MHz with respect to a human hand. The wireless power transmission device 101 may configure first data 671 at the first frequency as a reference. The wireless power transmission device 101 may identify pieces of data 672, 673, and 674 at different frequencies, and may identify slopes thereof compared to the reference. Referring to FIG. 6F and FIG. 6G, the slopes corresponding to the human body and the slopes corresponding to the conductor may be different, and thus it is possible to distinguish a human body/conductor, based on the slopes. Alternatively, the wireless power transmission device 101 may distinguish the human body/conductor, based on the average value of a plurality of pieces of data, and those skilled in the art will understand that there is no limitation on a method for distinguishing the human body/conductor.

For example, Table 1 shows an example of measurement and/or processing results at a plurality of frequencies in a case where there is no approaching object, in a case where the conductor is adjacent, and in a case where the human body is adjacent.

TABLE 1

| | No adjacent | | Human |
|---|---|---|---|
| | object | Conductor | body |
| Phase difference measured | −22.3 | 0.3 | −31.5 |
| at frequency of f1 | | | |
| Phase difference measured | 18.6 | 13.4 | −17.5 |
| at frequency of f2 | | | |
| Median value | −1.9 | 6.9 | −21.1 |
| Slope | 2.9 | 0.9 | 1 |

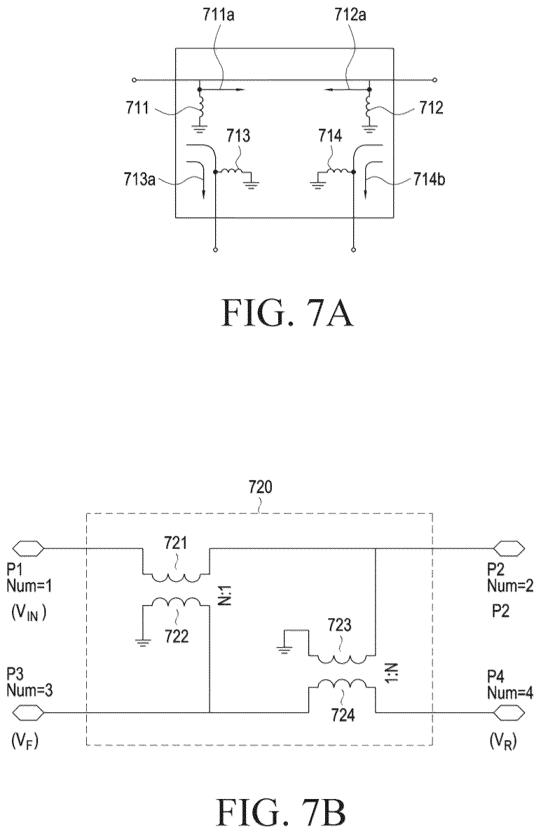

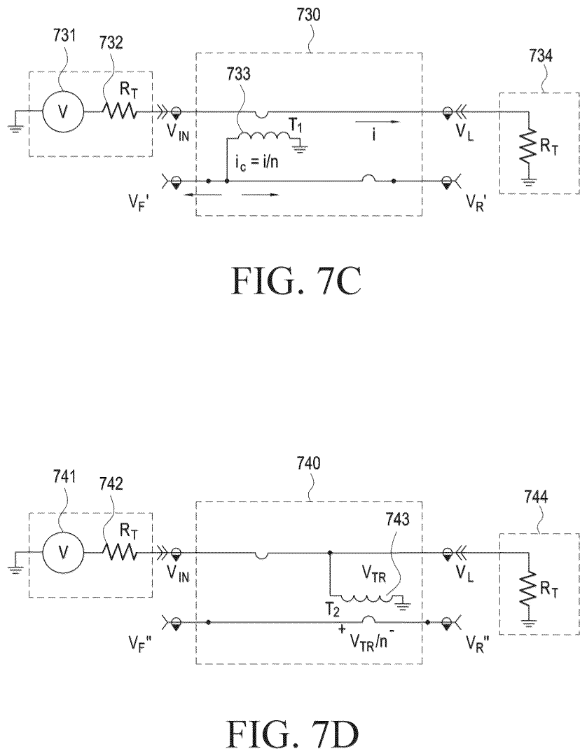

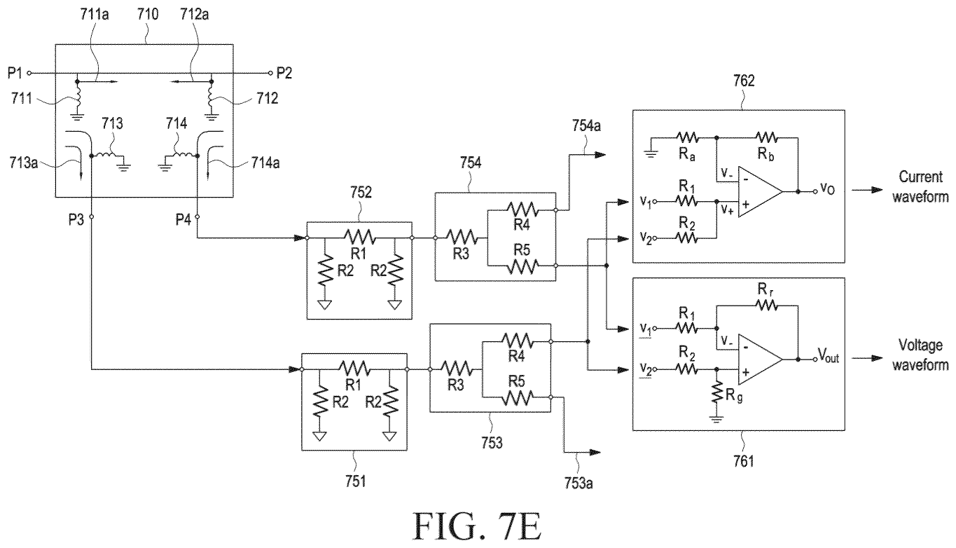

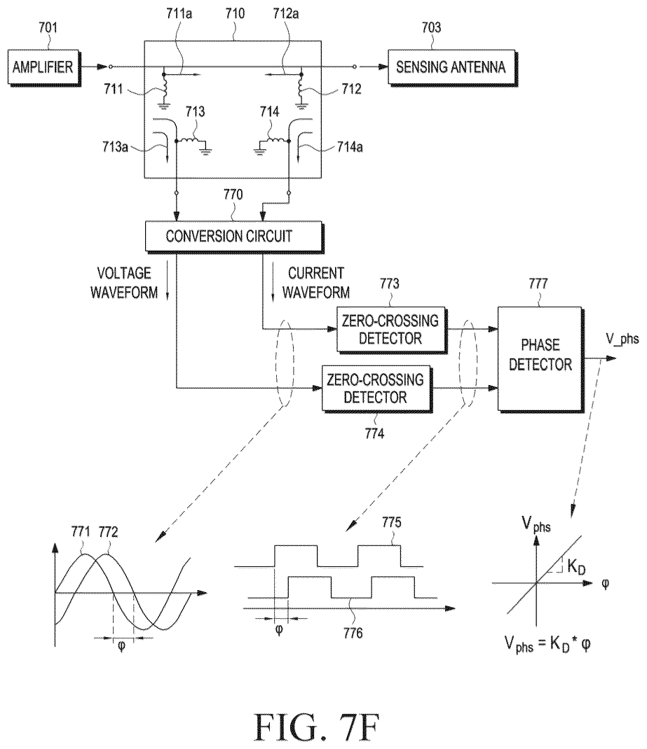

As shown in Table 1, the results of measuring a phase difference at a frequency of f1 may be different in the conductor and in the human body, the results of measuring a phase difference at a frequency of f2 may be different in the conductor and in the human body, median values (or average values) may be different in the conductor and in the human body, or slopes may be different in the conductor and in the human body. Accordingly, the wireless power transmission device 101 may identify whether an approaching object is a human body or a conductor, based on phase differences measured at one frequency or the result (e.g., at least one of a median value, an average value, or a slope) of processing phase differences measured at a plurality of frequencies. As described above, the wireless power transmission device 101 according to various embodiments may identify whether a human body is present and/or the distance to the human body, based on a phase voltage value, which is one of parameters corresponding to a phase difference between a current and a voltage. Hereinafter, various embodiments of identifying a phase voltage value will be described with reference to FIG. 7A to FIG. 7F.

FIG. 7A illustrates a coupler according to various embodiments.

The coupler 710 (e.g., the coupler 415 of FIG. 4A) according to various embodiments may include (or be connected to) an input terminal (RF INPUT) and an output terminal (RF OUTPUT). The input terminal (RF INPUT) may be connected to, for example, the amplifier 413 of FIG. 4A, and/or the output terminal (RF OUTPUT) may be connected to, for example, the filter 417 of FIG. 4A, but the disclosure is not limited thereto. The coupler 710 may include inductors 711 and 712 connected to a line (or a conductor or a rail) connecting the input terminal (RF INPUT) and the output terminal (RF OUTPUT). The line connecting the input terminal (RF INPUT) and the output terminal (RF OUTPUT) may be referred to as a main line for convenience of explanation. The coupler 710 may include (or be connected to) a coupled forward terminal (COUPLED FORWARD RF) configured to output a forward signal (F) and a coupled reverse terminal (COUPLED REVERSE RF) configured to output a reflected signal (R). The coupler 710 may include an inductor 713 connected to the coupled forward terminal (COUPLED FORWARD RF) and an inductor 714 connected to the coupled reverse terminal (COUPLED REVERSE RF). A forward signal 713a corresponding to a signal 711a may be provided to the coupled forward terminal (COUPLED FORWARD RF) by coupling of the inductors 711 and 713. A reflected signal 714a corresponding to a signal 712a may be provided to the coupled forward terminal (COUPLED FORWARD RF) by coupling of the inductors 712 and 714. The coupled forward terminal (COUPLED FORWARD RF) and the coupled reverse terminal (COUPLED REVERSE RF) may be connected to, for example, the conversion circuit 419 of FIG. 4A, and accordingly the conversion circuit 419 may receive the forward signal 713a and the reflected signal 714a.

FIG. 7B is an equivalent circuit diagram of the coupler of FIG. 7A.

An equivalent circuit 720 of the coupler 710 of FIG. 7A according to various embodiments may be connected to a first terminal P1, a second terminal P2, a third terminal P3, and a fourth terminal P4. For example, the first terminal P1 may correspond to the input terminal (RF INPUT) of FIG. 7A, the second terminal P2 may correspond to the output terminal (RF OUTPUT) of FIG. 7A, the third terminal P3 may correspond to the coupled forward terminal (COUPLED FORWARD RF) of FIG. 7A, and the fourth terminal P4 may correspond to the coupled reverse terminal (COUPLED REVERSE RF) of FIG. 7A. A voltage of Vm may be applied to the first terminal P1, a voltage of V_{L} may be applied to the second terminal P2, a voltage of V_{F} may be applied to the third terminal P3, and a voltage of V_{R} may be applied to the fourth terminal P4. The inductors 711, 712, 713, and 714 in the coupler 710 of FIG. 7A may correspond to inductors 721 and 722 forming an N:1 current transformer and inductors 723 and 724 forming a 1LN voltage transformer illustrated in FIG. 7B. The equivalent circuit 720 of FIG. 7B may be interpreted as superposition of a first sub-equivalent circuit 730 of FIG. 7C and a second sub-equivalent circuit 740 of FIG. 7D. FIG. 7C may be a sub-equivalent circuit associated with the current of the main line, and FIG. 7D may be a sub-equivalent circuit associated with the voltage of the main line. First, referring to FIG. 7C, a source having a voltage source 731 and a load 732 having a resistance value of R_{T} and a load 734 having a resistance value of R_{T} may be connected to the first sub-equivalent circuit 730. A voltage corresponding to a forward signal in the first sub-equivalent circuit 730 is referred to as V_{F}′, and a voltage corresponding to a reflected signal is referred to as V_{R}′. The first sub-equivalent circuit 730 may include an n:1 current transformer T1. If a current flowing in a main line 735 of the first sub-equivalent circuit 730 is i, a current i_{c} flowing in an induction line 736 may be i/n by the n:1 current transformer T1. i may be expressed by Equation 3, and i_{c} may be expressed by Equation 4.

$$[ Equation 3 ]$$

$$i = \frac{{V}_{IN} - {V}_{L}}{{R}_{T}}$$

$$[ Equation 4 ]$$

$${i}_{c} = \frac{i}{n} = \frac{{V}_{IN} - {V}_{L}}{{R}_{T}} \cdot \frac{1}{n}$$

V_{F}′ and V_{R}′ in FIG. 7C may be the same, and may have a value expressed by Equation 5.

$$[ Equation 5 ]$$

$${V}_{R}^{′} = {V}_{R}^{′} = {t}_{c} \frac{{R}_{T}}{2} = \frac{{V}_{IN} - {V}_{1}}{2 n}$$

Referring to FIG. 7D, a source having a voltage source 741 and a load 742 having a resistance value of R_{T} and a load 744 having a resistance value of R_{T} may be connected to the second sub-equivalent circuit 740. A voltage corresponding to a forward signal in the second sub-equivalent circuit 740 is referred to as V_{F}″, and a voltage corresponding to a reflected signal is referred to as V_{R}″. The second sub-equivalent circuit 740 may include a 1:n voltage transformer T2. If a voltage applied to a main line 745 of the second sub-equivalent circuit 740 is V_{TR}, a voltage applied to an induction line 746 may be V_{TR}/n. V_{TR} may be the sum of V_{N} and V_{L}. V_{F}″ may be expressed by Equation 6, and V_{R}″ may be expressed by Equation 7.

$$[ Equation 6 ]$$

$${V}_{F}^{″} = \frac{1}{2} \cdot \frac{{V}_{IN} + {V}_{L}}{n}$$

$$[ Equation 7 ]$$

$${V}_{R}^{″} = - \frac{1}{2} \cdot \frac{{V}_{IN} + {V}_{L}}{n}$$

V_{F} in FIG. 7B to which the superposition is applied may be expressed by Equation 8, and V_{R} in FIG. 7B may be expressed by Equation 9.

$$[ Equation 8 ]$$

$${V}_{F} = {V}_{F}^{′} + {V}_{F}^{″} = \frac{{V}_{IN} - {V}_{L}}{2 n} + \frac{{V}_{IN} + {V}_{L}}{2 n} = \frac{{V}_{IN}}{n}$$

$$[ Equation 9 ]$$

$${V}_{R} = {V}_{R}^{′} + {V}_{R}^{″} = \frac{{V}_{IN} - {V}_{L}}{2 n} + \frac{{V}_{IN} + {V}_{L}}{2 n} = 0$$

Equation 10 and Equation 11 may be established according to the foregoing description.

$$[ Equation 10 ]$$

$${i}_{c} = \frac{{V}_{F}}{{R}_{F}} + \frac{{V}_{R}}{{R}_{R}} \to i = ( {V}_{F} + {V}_{R} ) \cdot \frac{n}{2 {R}_{L}}$$

In Equation 10, R_{F} and R_{R} may be R_{L}. As shown in Equation 10, the sum of the voltages V_{F} and V_{R} of the output terminal of the coupler 710 may be proportional to the current i in the main line of the coupler 710.

$$[ Equation 11 ]$$

$$\frac{{V}_{TR}}{n} = {V}_{F} - {V}_{R} \to {V}_{TR} = ( {V}_{F} - {V}_{R} ) \cdot n$$

As shown in Equation 11, the subtraction of the voltages V_{F} and V_{R} of the output terminal of the coupler 710 may be proportional to the voltage V_{TR} of the main line of the coupler 710.

FIG. 7E illustrates a conversion circuit according to various embodiments.

According to various embodiments, the conversion circuit (e.g., the conversion circuit 419 of FIG. 4A) may include at least one of at least one attenuator 751 and 752, at least one splitter, a subtractor 761, or an adder. An attenuator 751A may be connected to the third terminal P3 of the coupler 710, and an attenuator 752 may be connected to the fourth terminal P4. The at least one attenuator may include at least one resistor R1 and R2 for an impedance of, for example, 50Ω. Each of the at least one attenuator 751 and 752 may be connected to each of at least one splitter 753 and 754. The at least one splitter 753 and 754 may include at least one resistor R3, R4, and R5 for dividing a voltage at a specified ratio. An output signal 753a from a splitter 753 may correspond to the level of a forward signal, and an output signal 754a from a splitter 754 may correspond to the level of a reflected signal. The output signal 753a and the output signal 754a may be used, for example, to identify a standing wave ratio, but is not limited thereto, and may not be used depending on a configuration, in which case the splitter 753 and 754 may not be included in a wireless power transmission device 101. The subtractor 761 may be a general subtractor implemented by an operational amplifier (OP-AMP). The subtractor 761 may receive a voltage corresponding to the forward signal and a voltage corresponding to the reflected signal, and may provide a subtraction result with the voltages. Accordingly, the subtractor 761 may output a voltage waveform. As shown in Expression 11, the subtraction result may be proportional to the voltage (V_{TR}) of the main line of the coupler 710. The adder 762 may be a general adder implemented by an OP-AMP. The adder 762 may receive the voltage corresponding to the forward signal and the voltage corresponding to the reflected signal, and may provide an addition result with the voltages. As shown in Equation 10, the subtraction result may be proportional to the current i in the main line of the coupler 710. Accordingly, the adder 762 may output a current waveform.

FIG. 7F illustrates a detection circuit according to various embodiments.

According to various embodiments, the coupler 710 may be connected to an amplifier 701 and a sensing antenna 703. The coupler 710 may be connected to a conversion circuit 770. As described in FIG. 7E, the conversion circuit 770 may output a voltage waveform 771 and a current waveform 772 by using a forward signal and a reflected signal input from the coupler 710. The phase of the voltage waveform 771 and the phase of the current waveform 772 may have a phase difference of y.

A detection circuit (e.g., the detection circuit 421 of FIG. 4A) according to various embodiments may include at least one of at least one zero-crossing detector 773 and 774 or a phase detector 777. A zero-crossing detector 773 may output a signal 776 for a zero-crossing point in the current waveform 772, and a zero-crossing detector 774 may output a signal 775 for a zero-crossing point in the voltage waveform 771. A phase detector 777 may output a phase voltage value V_phs corresponding to the phase difference Y, based on the signals 775, 776 for the zero-crossing points. For example, the phase detector 777 may be implemented so that the phase difference y has a proportional relationship with the phase voltage value V_phs (e.g., a proportional relationship of a slope of K_{D}) as illustrated in FIG. 7F, but those skilled in the art will understand that there is no limitation in implementing the relationship between the phase difference y and the phase voltage value V_phs. As described above, since the phase difference y and the phase voltage value V_phs have the relationship, the wireless power transmission device 101 may use the phase voltage value as a parameter corresponding to the phase difference. In various embodiments of the disclosure, the wireless power transmission device 101 may identify whether a human body is adjacent and/or the distance to the human body, based on the phase voltage value V_phs output from the detection circuit (e.g., the detection circuit 421 of FIG. 4A), but the phase voltage value is merely for illustration and those skilled in the art will understand that any parameter representing the phase difference may be used without limitation. In addition, those skilled in the art will understand that the phase difference in various embodiments of the disclosure may be replaced with the phase voltage value, for example, association information between the phase difference and the distance to the human body may be replaced with the association information between the phase voltage value and the distance to the human body.

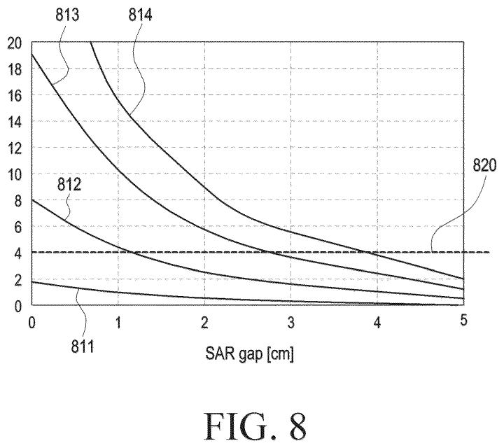

FIG. 8 illustrates SAR according to distance according to various embodiments.

According to various embodiments, a first graph 811 may represent SAR measured at various distances while a first current value (e.g., 6 A) is applied to a power transmission coil 222. For example, the highest SAR may be measured at the surface (i.e., 0 cm) while the first current value is applied to the power transmission coil 222, and the SAR may decrease as the distance increases. A second graph 812, a third graph 813, and a fourth graph 814 may represent SAR measured at various distances while a second current value (e.g., 13 A), a third current value (e.g., 20 A), and a fourth current value (e.g., 25 A) are applied to the power transmission coil 222, respectively. As illustrated in FIG. 8, as a higher current value is applied to the power transmission coil 222, a higher SAR may be measured at the same level. An SAR requirement may be that SAR at a point where a human body is positioned does not exceed a threshold SAR of 4 mW/g. A wireless power transmission device 101 may identify a target current (or a maximum current value) applied to the power transmission coil 222, based on the distance to a human body 180 identified according to various embodiments. For example, when the distance to the human body 180 is identified to be 4 cm, the wireless power transmission device 101 may identify the fourth current value (e.g., 25 A) corresponding to a current value of the threshold SAR (e.g., 4 mW/g) corresponding to 4 cm as the target current (or the maximum current value). For example, when the distance to the human body 180 is identified to be 1.1 cm, the wireless power transmission device 101 may identify the second current value (e.g., 13 A) corresponding to a current value of the threshold SAR (e.g., 4 mW/g) corresponding to 1.1 cm as the target current (or maximum current value). The wireless power transmission device 101 may store relationship information between various distances to the human body and the target current (or maximum current value) corresponding to the threshold SAR. The wireless power transmission device 101 may identify the target current (or maximum current value), based on the identified distance to the human body and the relationship information. The wireless power transmission device 101 may control a current less than or equal to the target current (or maximum current value) to be applied to the power transmission coil 222. The target current (or maximum current value) may be configured to be smaller by a specified margin value than a current corresponding to the threshold SAR (e.g., 4 mW/g) according to the SAR requirement. Those skilled in the art will understand that the threshold SAR in various embodiments of the disclosure may refer to the threshold SAR according to the SAR requirement or refer to a value configured to be smaller by the specified margin value than the threshold SAR according to the SAR requirement.

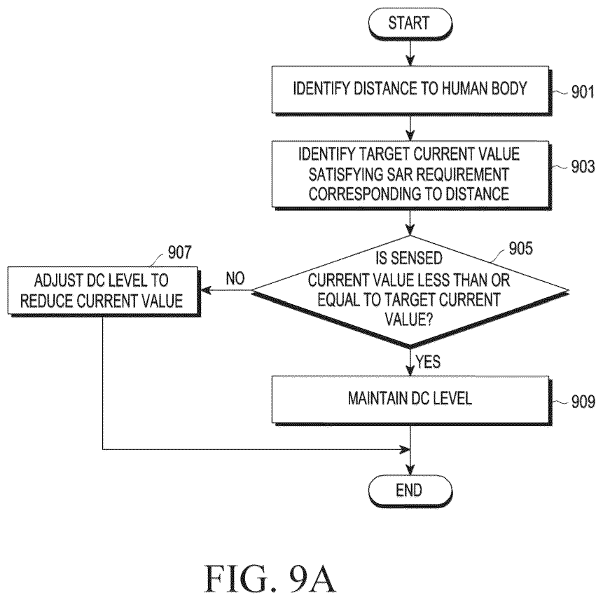

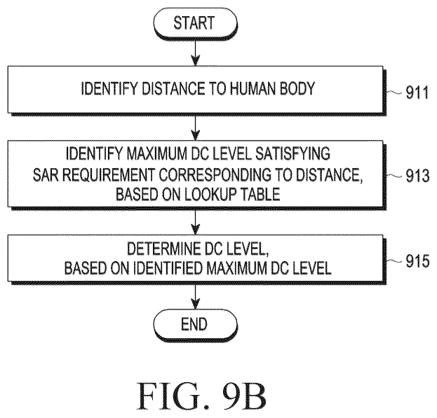

FIG. 9A is a flowchart illustrating an operating method of a wireless power transmission device according to various embodiments.

According to various embodiments, in operation 901, the wireless power transmission device 101 (e.g., a controller 210) may identify the distance to a human body. Since various embodiments of identifying the distance to the human body have been described above, a repeated description is not made herein. In operation 903, the wireless power transmission device 101 may identify a target current value (or maximum current value) corresponding to a power transmission coil 222 that satisfies an SAR requirement corresponding to the distance. As described with reference to FIG. 8, the wireless power transmission device 101 may store relationship information between various distances to the human body and the target current (or maximum current value) corresponding to a threshold SAR (e.g., 4 mW/g). The wireless power transmission device 101 may identify the target current (or maximum current value), based on the identified distance to the human body and the relationship information. In operation 905, the wireless power transmission device 101 may identify whether a sensed current value is less than or equal to the target current value. The wireless power transmission device 101 may identify whether the current value applied to the power transmission coil 222 sensed by at least one sensor (e.g., at least one sensor 437 and/or 439 of FIG. 4A) is less than or equal to the target current value. When the sensed current value exceeds the target current value (905—No), the wireless power transmission device 101 may adjust a DC level to reduce the current value in operation 907. For example, the wireless power transmission device 101 may control a DC/DC converter 431 of FIG. 4A to reduce an output voltage of the DC/DC converter 431. When the sensed current value is equal to or greater than the target current value (905—Yes), the wireless power transmission device 101 may maintain the DC level in operation 909. The above example is for illustration, and those skilled in the art will understand that the wireless power transmission device 101 may adjust the DC level, based on a request from a wireless power reception device 103, a result of measurement in the wireless power reception device 103 (e.g., a voltage and/or current of an output terminal of the rectifier, but not limited), and/or wireless charging efficiency, and the DC level is maintained when there is no reason for adjusting the DC level. Even though adjustment of the DC level is required, the wireless power transmission device 101 may control the DC/DC converter 431 so that the sensed current value is less than or equal to the target current value. According to the foregoing description, the SAR occurring at a point of the human body 180 may be maintained below the threshold SAR.

FIG. 9B is a flowchart illustrating an operating method of a wireless power transmission device according to various embodiments.

According to various embodiments, in operation 911, the wireless power transmission device 101 (e.g., a controller 210) may identify the distance to a human body. Since various embodiments of identifying the distance to the human body have been described above, a repeated description is not made herein. In operation 913, the wireless power transmission device 101 may identify a maximum DC level that satisfies an SAR requirement corresponding to the distance, based on a lookup table. For example, the wireless power transmission device 101 may identify the maximum DC level (i.e., a maximum output voltage value of the DC/DC converter 431) that satisfies the SAR requirement according to various distances to the human body. Table 2 is an example of the lookup table.

TABLE 2

| | Maximum input |
|---|---|
| | DC level |
| Distance to | for satisfying SAR |
| human body [cm] | requirement [V] |
| 1 | 7 |
| 2 | 8 |
| 3 | 10 |
| 4 | 12 |
| 5 | 15 |
| 6 | 17 |
| 7 | 19 |
| 8 | 21 |
| 9 | 21 |
| 10 | 21 |

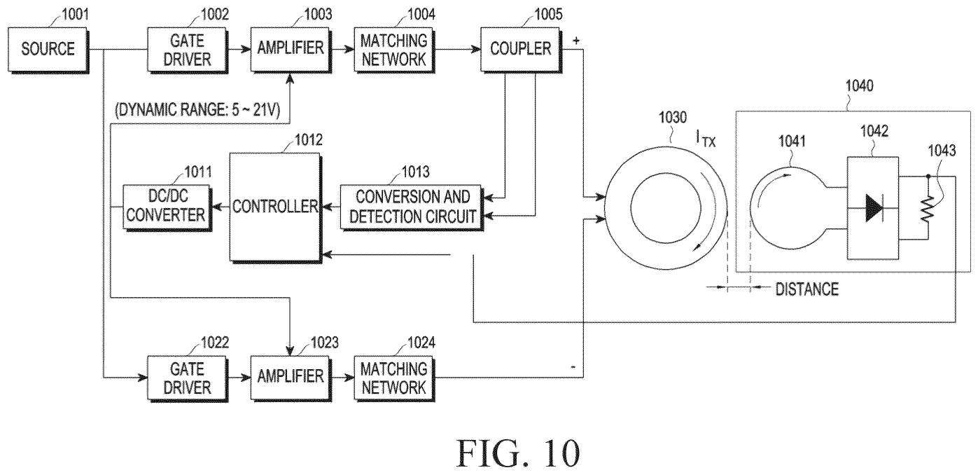

The wireless power transmission device 101 may identify a maximum DC level value corresponding to the distance to the human body identified in operation 911 by referring to the lookup table, for example, Table 2. The wireless power transmission device 101 may determine a DC level, based on the identified maximum DC level in operation 915. The wireless power transmission device 101 may control a DC/DC converter 413, based on the identified DC level. According to the foregoing description, the SAR occurring at a point of the human body 180 may be maintained below the threshold SAR. FIG. 10 is a flowchart illustrating an operating method of a wireless power transmission device according to various embodiments.

According to various embodiments, the wireless power transmission device 101 may include at least one of a source 1001, gate drivers 1002 and 1022, amplifiers 1003 and 1023, matching networks 1004 and 1024, couplers 1005 and 1025, a DC/DC converter 1011, a controller 1012, a conversion and detection circuit 1013, a power transmission coil 1030, or a sensor 1040.

According to various embodiments, the source 1001 may output a signal configured for power transmission. The gate drivers 1002 and 1022 may provide gate voltages respectively to the amplifiers 1003 and 1023 by using the signal from the source 1001. In the embodiments of FIG. 10, the wireless power transmission device 101 may perform wireless charging by using differential signals. The phase of the gate voltage output from the gate driver 1002 may be 180-degree different from the phase of the gate voltage output from the gate driver 1022. The amplifiers 1003 and 1023 may output amplified signals respectively by using the gate voltages and a driving voltage provided from the DC/DC converter 1011. The driving voltage may be included in a dynamic range from 5 V to 21 V, which is for illustration and is not limited. The amplified signals may be differential signals having a phase difference of, for example, 180 degrees. The amplified signal output from the amplifier 1003 may be provided to the power transmission coil 1030 through the matching network 1004 and the coupler 1005. The amplified signal output from the amplifier 1023 may be provided to the power transmission coil 1030 through the matching network 1024. The matching networks 1004 and 1024 may include at least one element for impedance matching. The coupler 1005 may be, for example, a directional coupler, and may provide a forward signal and a reflected signal to the conversion and detection circuit 1013. The conversion and detection circuit 1013 may provide at least one parameter (e.g., a phase voltage value) corresponding to a phase difference between a current and a voltage in the coupler 1005 to the controller 1012 by using the forward signal and the reflected signal. As described above, the conversion and detection circuit 1013 may obtain a current waveform and a voltage waveform, based on addition and subtraction using the forward signal and the reflected signal, and may output at least one parameter (e.g., a phase voltage value) corresponding to a phase difference of the current waveform and the voltage waveform. The controller 1012 may identify whether an adjacent object is a human body or a conductor and/or the distance to the object, based on the at least one parameter (e.g., the phase voltage value) corresponding to the phase difference between the current and the voltage. The controller 1012 may control the DC/DC converter 1011, based on the distance to the human body, to satisfy an SAR requirement. Since a component for identifying whether the adjacent object is the human body or the conductor and/or the distance to the object based on the at least one parameter (e.g., the phase voltage value) corresponding to the phase difference between the current and the voltage has been described above, a description thereof is not repeated herein.

According to various embodiments, a wireless power transmission device may include a power transmission coil, a first circuit electrically connected to the power transmission coil and configured to provide first power of a first frequency to the power transmission coil, a sensing antenna configured to detect a human body, a second circuit electrically connected to the sensing antenna, and a controller, wherein the controller may be configured to control the first circuit so that the first power of the first frequency is provided to the power transmission coil, control the second circuit so that second power of a second frequency, which is different from the first frequency, is provided to the sensing antenna while the first power is provided to the power transmission coil, obtain at least one parameter based on at least one sensing result measured with respect to at least one point of the second circuit from the second circuit, identify a distance from the sensing antenna to a human body adjacent to the sensing antenna, based on the at least one parameter, and control the first circuit to adjust a level of the first power, based on the distance from the sensing antenna to the human body.

According to various embodiments, as at least part of an operation of obtaining the at least one parameter based on the at least one sensing result measured at the at least one point of the second circuit from the second circuit, the controller may be configured to obtain a parameter corresponding to a phase difference between a current and a voltage at the at least one point as the at least one parameter.

According to various embodiments, the second circuit may include a source configured to provide a signal of the second frequency, an amplifier configured to amply the signal of the second frequency to output the signal to the sensing antenna, a coupler connected to the source and the amplifier therebetween and configured to output a forward signal and a reflected signal, an adder configured to output a first waveform of the current, based on an addition result of the forward signal and the reflected signal, and a subtractor configured to output a second waveform of the voltage, based on a subtraction result of the forward signal and the reflected signal.

According to various embodiments, the second circuit may include a first zero-crossing detector configured to output a first signal associated with zero-crossing points of the first waveform of the current, a second zero-crossing detector configured to output a second signal associated with zero-crossing points of the second waveform of the voltage, and a phase detector configured to output a phase voltage value corresponding to the phase difference between the current and the voltage by using the first signal and the second signal, and the phase voltage value may be the at least one parameter.

According to various embodiments, as at least part of an operation of identifying the distance from the sensing antenna to the human body adjacent to the sensing antenna, based on the at least one parameter, the controller may be configured to identify the distance to the human body, based on association information between a plurality of values of the at least one parameter and a plurality of distances to the human body and a value of the at least one parameter.

According to various embodiments, as at least part of an operation of controlling the first circuit to adjust the level of the first power, based on the distance from the sensing antenna to the human body, the controller may be configured to control the first circuit to adjust the level of the first power to be less than or equal to a target level satisfying an SAR requirement corresponding to the distance to the human body.

According to various embodiments, the wireless power transmission device may further include a sensor configured to sense a current flowing in the power transmission coil, and, as at least part of an operation of controlling the first circuit to adjust the level of the first power to be less than or equal to the target level satisfying the SAR requirement corresponding to the distance to the human body, the controller may be configured to identify the sensed current flowing in the power transmission coil from the sensor, and control the first circuit so that the current is less than or equal to a target current value as the target level.

According to various embodiments, the first circuit may include a source configured to supply a signal of the first frequency, an amplifier configured to amplify the signal of the first frequency to provide the signal to the power transmission coil, and a DC/DC converter configured to provide a driving voltage to the amplifier, and the controller may be configured to control the DC/DC converter so that the current is less than or equal to the target current value, as at least part of an operation of controlling the first circuit so that the current is less than or equal to the target current value.

According to various embodiments, the sensor may include a pickup coil and a rectifier configured to rectify AC power by electromagnetic waves generated from the power transmission coil due to application of the first power, output from the pickup coil, the controller may be configured to identify an output voltage of the rectifier, as at least part of an operation of identifying the sensed current flowing in the power transmission coil from the sensor, and the controller may be configured to control the first circuit so that the output voltage of the rectifier is less than or equal to a target voltage value corresponding to the target current value, as at least part of an operation of controlling the first circuit so that the current is less than or equal to the target current value.

According to various embodiments, as at least part of an operation of controlling the first circuit to adjust the level of the first power to be less than or equal to the target level satisfying the SAR requirement corresponding to the distance to the human body, the controller may be configured to identify a control value of the first circuit, based on association information between a plurality of distances to the human body and control values of the first circuit and the distance to the human body, and control the first circuit by using the control value.

According to various embodiments, the first circuit may include a source configured to provide a signal of the first frequency, an amplifier configured to amplify the signal of the first frequency to provide the signal to the power transmission coil, and a DC/DC converter configured to provide a driving voltage to the amplifier, and the control values of the first circuit may be driving voltages provided by the DC/DC converter.

According to various embodiments, as at least part of an operation of identifying the distance from the sensing antenna to the human body adjacent to the sensing antenna, based on the at least one parameter, the controller may be configured to identify the distance to the human body, based on identifying that an object adjacent to the sensing antenna is the human body.

According to various embodiments, the controller may be further configured to identify that the object adjacent to the sensing antenna is the human body, based on the at least one parameter satisfying a specified first condition and/or a changed level of the first power applied to the power transmission coil satisfying a specified second condition.

According to various embodiments, the controller may be further configured to identify that the object adjacent to the sensing antenna is the human body, based on measured results of the at least one parameter at a plurality of times satisfying a specified condition.

According to various embodiments, the controller may be further configured to identify that the object adjacent to the sensing antenna is the human body, based on measured results of the at least one parameter at a plurality of frequencies satisfying a specified condition.

According to various embodiments, an operating method of a wireless power transmission device including a power transmission coil, a first circuit electrically connected to the power transmission coil and configured to provide first power of a first frequency to the power transmission coil, a sensing antenna configured to detect a human body, and a second circuit electrically connected to the sensing antenna may include controlling the first circuit so that the first power of the first frequency is provided to the power transmission coil, controlling the second circuit so that second power of a second frequency, which is different from the first frequency, to the sensing antenna while the first power is provided to the power transmission coil, obtaining at least one parameter based on at least one sensing result measured at at least one point of the second circuit from the second circuit, identifying a distance from the sensing antenna to a human body adjacent to the sensing antenna, based on the at least one parameter, and controlling the first circuit to adjust a level of the first power, based on the distance from the sensing antenna to the human body.

According to various embodiments, the identifying of the distance from the sensing antenna to the human body adjacent to the sensing antenna, based on the at least one parameter may identify the distance to the human body, based on association information between a plurality of values of the at least one parameter and a plurality of distances to the human body and a value of the at least one parameter.

According to various embodiments, the controlling the first circuit to adjust the level of the first power, based on the distance from the sensing antenna to the human body may control the first circuit to adjust the level of the first power to be less than or equal to a target level satisfying an SAR requirement corresponding to the distance to the human body.

According to various embodiments, the controlling the first circuit to adjust the level of the first power to be less than or equal to the target level satisfying the SAR requirement corresponding to the distance to the human body may include identifying the current flowing in the power transmission coil, and controlling the first circuit so that the current is less than or equal to a target current value as the target level.

According to various embodiments, the controlling the first circuit to adjust the level of the first power to be less than or equal to the target level satisfying the SAR requirement corresponding to the distance to the human body may include identifying a control value of the first circuit, based on association information between a plurality of distances to the human body and control values of the first circuit and the distance to the human body, and controlling the first circuit by using the control value.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., program) including one or more instructions that are stored in a storage medium (e.g., internal memory or external memory) that is readable by a machine (e.g., the electronic device 101). For example, a processor of the machine (e.g., the wireless power transmission device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to various embodiments, there may be provided a wireless power transmission device and an operating method thereof for identifying the distance to a human body, based on a parameter associated with a radio-frequency (RF) signal of a frequency different from a frequency for wireless power transmission, and adjusting the level of transmission power for charging, based on the identified distance.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. A wireless power transmission device comprising:
a power transmission coil;
a first circuit electrically connected to the power transmission coil and configured to provide first power of a first frequency to the power transmission coil;
a sensing antenna configured to detect a human body;
a second circuit electrically connected to the sensing antenna; and
a controller configured to:
control the first circuit to provide the first power of the first frequency to the power transmission coil;
control the second circuit to provide a second power of a second frequency, which is different from the first frequency, to the sensing antenna while the first power is provided to the power transmission coil;
obtain at least one parameter based on at least one sensing result obtained at at least one point of the second circuit from the second circuit;
identify a distance from the sensing antenna to a human body adjacent to the sensing antenna, based on the at least one parameter; and
control the first circuit to adjust a level of the first power, based on the distance from the sensing antenna to the human body.

2. The wireless power transmission device of claim 1, wherein the at least one parameter comprises a parameter corresponding to a phase difference between a current and a voltage at the at least one point.

3. The wireless power transmission device of claim 2, wherein the second circuit comprises:
a source configured to provide a signal of the second frequency;
an amplifier configured to amply the signal of the second frequency to output the signal to the sensing antenna;
a coupler connected to the source with the amplifier therebetween and configured to output a forward signal and a reflected signal;
an adder configured to output a first waveform of the current, based on an addition result of the forward signal and the reflected signal; and
a subtractor configured to output a second waveform of the voltage, based on a subtraction result of the forward signal and the reflected signal.

4. The wireless power transmission device of claim 3, wherein the second circuit comprises:
a first zero-crossing detector configured to output a first signal associated with zero-crossing points of the first waveform of the current;
a second zero-crossing detector configured to output a second signal associated with zero-crossing points of the second waveform of the voltage; and
a phase detector configured to output a phase voltage value corresponding to the phase difference between the current and the voltage based on the first signal and the second signal, and
wherein the parameter comprises the phase voltage value.

5. The wireless power transmission device of claim 1, wherein the controller is further configured to identify the distance from the sensing antenna to the human body adjacent to the sensing antenna, based on association information between a plurality of values of the at least one parameter and a plurality of distances to the human body and a value of the at least one parameter.

6. The wireless power transmission device of claim 1, wherein the controller is further configured to control the first circuit to adjust the level of the first power, based on the distance from the sensing antenna to the human body, to be less than or equal to a target level satisfying an SAR requirement corresponding to the distance to the human body.

7. The wireless power transmission device of claim 6, further comprising:
a sensor configured to sense a current flowing in the power transmission coil,
wherein the controller is further configured to control the first circuit to adjust the level of the first power to be less than or equal to the target level satisfying the SAR requirement corresponding to the distance to the human body, by identifying the current flowing in the power transmission coil sensed by the sensor, and controlling the first circuit to cause the current to be less than or equal to a target current value as the target level.

8. The wireless power transmission device of claim 7, wherein the first circuit comprises:
a source configured to supply a signal of the first frequency;
an amplifier configured to amplify the signal of the first frequency to provide the signal to the power transmission coil; and
a DC/DC converter configured to provide a driving voltage to the amplifier, and
wherein the controller is further configured to control the DC/DC converter to cause the current to be less than or equal to the target current value.

9. The wireless power transmission device of claim 7, wherein the sensor comprises:
a pickup coil; and
a rectifier configured to rectify AC power by electromagnetic waves generated from the power transmission coil due to application of the first power output from the pickup coil,
wherein the controller is further configured to identify an output voltage of the rectifier, as at least part of an operation of identifying the current flowing in the power transmission coil sensed by the sensor, and
wherein the controller is further configured to control the first circuit to cause the output voltage of the rectifier to be less than or equal to a target voltage value corresponding to the target current value.

10. The wireless power transmission device of claim 6, wherein the controller is further configured to control the first circuit to adjust the level of the first power to be less than or equal to the target level satisfying the SAR requirement corresponding to the distance to the human body, by identifying a control value of the first circuit, based on association information between a plurality of distances to the human body and control values of the first circuit and the distance to the human body, and control the first circuit based on the control value.

11. The wireless power transmission device of claim 10, wherein the first circuit comprises:
a source configured to provide a signal of the first frequency;
an amplifier configured to amplify the signal of the first frequency to provide the signal to the power transmission coil; and
a DC/DC converter configured to provide a driving voltage to the amplifier, and
wherein the control values of the first circuit comprise driving voltages provided by the DC/DC converter.

12. The wireless power transmission device of claim 1, wherein the controller is further configured to identify the distance from the sensing antenna to the human body adjacent to the sensing antenna by identifying the distance to the human body, based on an object adjacent to the sensing antenna being identified as the human body.

13. The wireless power transmission device of claim 12, wherein the controller is further configured to identify that the object adjacent to the sensing antenna is the human body, based on the at least one parameter satisfying a specified first condition or a changed level of the first power applied to the power transmission coil satisfying a specified second condition.

14. The wireless power transmission device of claim 12, wherein the controller is further configured to identify that the object adjacent to the sensing antenna is the human body, based on measured results of the at least one parameter at a plurality of times satisfying a specified condition.

15. The wireless power transmission device of claim 12, wherein the controller is further configured to identify that the object adjacent to the sensing antenna is the human body, based on measured results of the at least one parameter at a plurality of frequencies satisfying a specified condition.
